(19) United States
(12) Patent Application Publication
(10) Pub. No.: US 2026/0066221 A1
(43) Pub. Date: Mar. 5, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Kota TANIKAWA, Kyoto-shi (JP); Manabu TAKUSARI, Kyoto-shi (JP); Hiroyuki YASHIKI, Kyoto-shi (JP)

(21) Appl. No.: 19/318,294

(22) Filed: Sep. 3, 2025

(30) Foreign Application Priority Data
Sep. 5, 2024 (JP) 2024-153004

(51) Int. Cl. H01J 37/317; H01J 37/304; H01L 21/67

(52) U.S. Cl. CPC H01J 37/317; H01J 37/304; H01J 2237/0048; H01J 2237/022; H01J 2237/24564

(57) ABSTRACT

A substrate processing apparatus includes an electrostatic charging unit and a processing unit. The electrostatic charging unit includes an electrostatic charger positively charging a first main surface of a substrate. The processing unit includes a processing chamber, and performs a process which includes at least one of heating of the substrate in the processing chamber and supply of a processing gas to the substrate and which involves the generation of metal ions in the processing chamber.

### BACKGROUND

### Technical Field

The present disclosure relates to a substrate processing apparatus and a substrate processing method.

### Description of the Background Art

Substrate processing apparatuses which use ozone gas to process substrates have been hitherto proposed (for example, Japanese Patent Application Laid-Open No. 2022-187165). In Japanese Patent Application Laid-Open No. 2022-187165, a substrate processing apparatus includes a heat treatment chamber, an ozone gas supply line for supplying ozone gas to the heat treatment chamber, and an exhaust line for discharging the gas from the heat treatment chamber to the outside. A substrate is transported into the heat treatment chamber, and is placed in a horizontal attitude. Ozone gas is supplied through the ozone gas supply line into the heat treatment chamber, and acts on a main surface of the substrate. The ozone gas is able to oxidize and decompose an organic film on the main surface of the substrate, for example. The ozone gas is discharged from the heat treatment chamber through the exhaust line to the outside.

### SUMMARY

According to one aspect, a substrate processing apparatus comprises: an electrostatic charging unit including an electrostatic charger for positively charging a first main surface of a substrate having the first main surface and a second main surface; and a processing unit including a processing chamber and for performing a process including at least one of the heating of the substrate in the processing chamber and the supply of a processing gas to the substrate, the process involving the generation of metal ions in the processing chamber.

According to one aspect, a method of processing a substrate, comprising: positively charging a first main surface of a substrate having the first main surface and a second main surface; and performing a process including at least one of the heating of the substrate in a processing chamber and the supply of a processing gas to the substrate, the process involving the generation of metal ions in the processing chamber.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically showing an example of the configuration of a substrate processing apparatus;

FIG. 2 is a block diagram schematically showing an example of the internal configuration of a controller;

FIG. 3 is a view schematically showing an example of the configuration of a dry processing unit;

FIG. 4 is a sectional view schematically showing an example of part of the configuration of a substrate receiving part;

FIG. 5 is a flow diagram showing an example of the operation of the dry processing unit;

FIG. 6 is a view schematically showing an example of the state of an electrostatic charging unit;

FIG. 7 is an enlarged view showing an example of the state of a gas bake unit;

FIG. 8 is a view schematically showing another example of the configuration of the electrostatic charging unit;

FIG. 9 is a view schematically showing an example of the configuration of the electrostatic charging unit according to a second embodiment;

FIG. 10 is a flow diagram showing an example of the operation of the dry processing unit according to the second embodiment;

FIG. 11 is a view schematically showing an example of the configuration of the electrostatic charging unit according to a third embodiment;

FIG. 12 is a view schematically showing a first example of the configuration of the electrostatic charging unit according to a fourth embodiment;

FIG. 13 is a view schematically showing a second example of the configuration of the electrostatic charging unit according to the fourth embodiment;

FIG. 14 is a view schematically showing a third example of the configuration of the electrostatic charging unit according to the fourth embodiment;

FIG. 15 is a view schematically showing a fourth example of the configuration of the electrostatic charging unit according to the fourth embodiment;

FIG. 16 is a view schematically showing a first example of the configuration of the electrostatic charging unit according to a fifth embodiment;

FIG. 17 is a plan view schematically showing an example of the configuration of a guiding member;

FIG. 18 is a view schematically showing a second example of the configuration of the electrostatic charging unit according to the fifth embodiment;

FIG. 19 is a view schematically showing a first example of the configuration of the electrostatic charging unit according to a sixth embodiment;

FIG. 20 is a flow diagram showing a first example of the operation of the electrostatic charging unit according to the sixth embodiment;

FIG. 21 is a flow diagram showing a second example of the operation of the electrostatic charging unit according to the sixth embodiment;

FIG. 22 is a view schematically showing a second example of the configuration of the electrostatic charging unit according to the sixth embodiment;

FIG. 23 is a view schematically showing a third example of the configuration of the electrostatic charging unit according to the sixth embodiment;

FIG. 24 is a view schematically showing a fourth example of the configuration of the electrostatic charging unit according to the sixth embodiment;

FIG. 25 is a flow diagram showing a first example of the operation of the electrostatic charging unit according to the fourth example of the sixth embodiment;

FIG. 26 is a flow diagram showing a second example of the operation of the electrostatic charging unit according to the fourth example of the sixth embodiment;

FIGS. 27A and 27B are views schematically showing a first example of the electrostatic charging unit according to a seventh embodiment;

FIG. 28 is a view schematically showing a second example of the configuration of the electrostatic charging unit according to the seventh embodiment;

FIG. 29 is a view schematically showing an example of the configuration of a tower of the substrate processing apparatus according to an eighth embodiment;

FIG. 30 is a view schematically showing another example of the configuration of the substrate processing apparatus according to the eighth embodiment;

FIG. 31 is a view schematically showing an example of the configuration of the electrostatic charging unit according to a ninth embodiment; and

FIG. 32 is a flow diagram showing an example of the operation of a wet processing unit according to the ninth embodiment.

### DESCRIPTION OF THE EMBODIMENTS

In Japanese Patent Application Laid-Open No. 2022-187165, metal may be employed, for example, as a material which forms inner walls of the chamber and the supply line (i.e., a supply pipe). An example of the metal includes stainless alloys (known also as stainless steel). The stainless alloys contain iron as a main component, and contain various chemical components such as carbon, silicon, manganese, phosphorus, sulfur, nickel, chromium, molybdenum, copper, and nitrogen as accessory components.

When gas reacts with the inner walls of the chamber and the inner walls of the supply pipe, metal can flow out of the inner walls into the supply pipe in an ionic state. There is a danger that these metal ions adhere to the substrate in the chamber. In other words, there is a danger that metal contamination of the substrate occurs.

It is therefore an object of the present disclosure to provide a technique capable of processing a substrate while reducing the likelihood of metal contamination of the substrate.

Embodiments according to the present disclosure will now be described in detail with reference to the drawings. In the drawings, the dimensions of components and the number of components are shown in exaggeration or in simplified form, as appropriate, for the sake of easier understanding. Like reference numerals and characters are used to designate parts similar in configuration and in function, and repetition in description is dispensed with in the following description.

In the following description, similar components are designated by and shown using the same reference numerals and characters, and shall have similar designations and functions. Thus, these components will not be described in detail in some cases for the purpose of avoiding repetition in description.

In the case where ordinal numerals such as “first”, “second”, or the like are used in the following description, these terms shall be used for the sake of convenience and for the purpose of facilitating the understanding of the details of the embodiments, and shall not be limited to the order caused by the ordinal numerals.

Expressions indicating relative or absolute positional relationships (e.g., “in one direction”, “along one direction”, “parallel”, “orthogonal”, “center”, “concentric”, and “coaxial”), when used, shall represent not only the exact positional relationships but also a state in which the angle or distance is relatively displaced to the extent that tolerances or similar functions are obtained, unless otherwise specified. Expressions indicating equal states (e.g., “identical”, “equal”, and “homogeneous”), when used, shall represent not only a state of quantitative exact equality but also a state in which there are differences that provide tolerances or similar functions, unless otherwise specified. Expressions indicating shapes (e.g., “rectangular” and “cylindrical”), when used, shall represent not only the geometrically exact shapes but also shapes having, for example, unevenness or chamfers to the extent that the same level of effectiveness is obtained, unless otherwise specified. An expression such as “comprising”, “equipped with”, “provided with”, “including”, or “having” a component, when used, is not an exclusive expression that excludes the presence of other components. The expression “at least one of A, B, and C”, when used, includes “A only”, “B only”, “C only”, “any two of A, B, and C”, and “all of A, B, and C”.

### First Embodiment

### <Overall Configuration of Substrate Processing Apparatus>

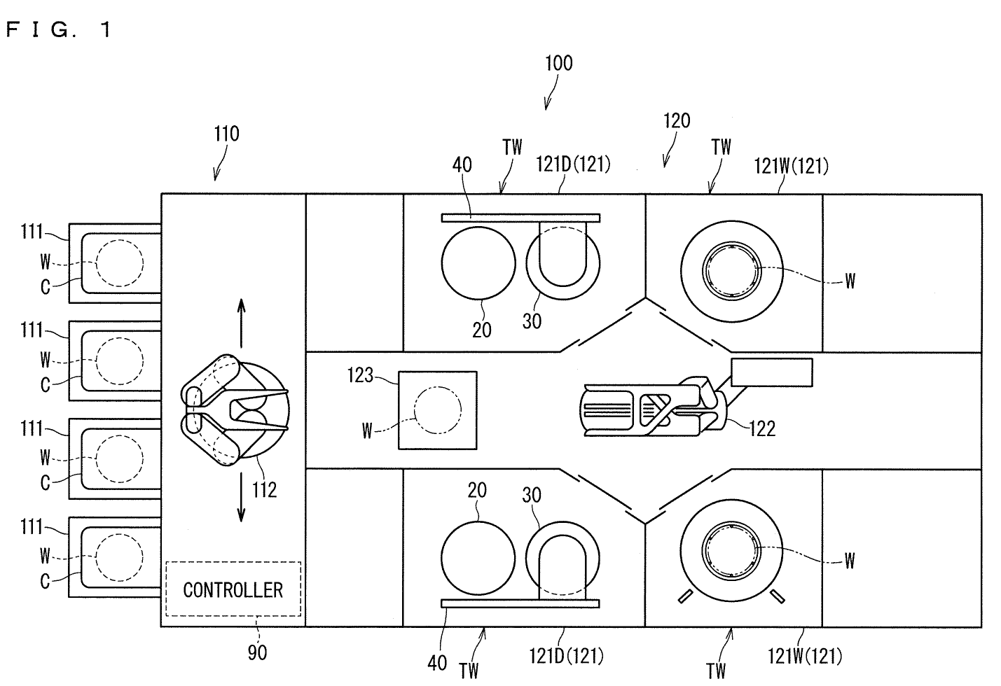

FIG. 1 is a plan view schematically showing an example of the configuration of a substrate processing apparatus 100. The substrate processing apparatus 100 is a single-wafer type processing apparatus which processes substrates W one by one.

Examples of a substrate W include a semiconductor wafer, a substrate for a liquid crystal display, a substrate for an organic Electroluminescence (EL), a substrate for a Flat Panel Display (FPD), a substrate for an optical display, a substrate for a magnetic disk, a substrate for an optical disk, a substrate for a magneto-optical disk, a substrate for a photomask, and a substrate for a solar cell. The substrate W has a thin planar shape. In the following description, it is assumed that the substrate W is a semiconductor wafer. The substrate W is disk-shaped, for example. The substrate W has a diameter of approximately 300 mm, for example, and has a thickness between approximately 0.5 and 3 mm, for example.

In the example of FIG. 1, the substrate processing apparatus 100 includes an indexer block 110, a processing block 120, and a controller 90. The processing block 120 is a part for mainly processing a substrate W. The indexer block 110 is a part for mainly transporting a substrate W between the outside of the substrate processing apparatus 100 and the processing block 120.

The indexer block 110 includes at least one load port 111 and a first transport part 112. A substrate container (referred to hereinafter as a carrier) C transported from the outside is placed on the load port 111. The carrier C accommodates multiple substrates W, for example, arranged in vertically spaced apart relation. In the example of FIG. 1, multiple load ports 111 are arranged.

The first transport part 112 is a transport robot capable of taking an unprocessed substrate W out of the carrier C placed on each of the load ports 111. The first transport part 112 is referred to also as an indexer robot. The first transport part 112 transports the unprocessed substrate W taken out of the carrier C to the processing block 120. The processing block 120 is capable of processing the unprocessed substrate W. The first transport part 112 is also capable of receiving a processed substrate W from the processing block 120, and transporting the processed substrate W to the carrier C of each of the load ports 111.

In the example of FIG. 1, the processing block 120 includes multiple processing units 121 and a second transport part 122. The second transport part 122 is a transport robot for transporting a substrate W between the first transport part 112 and the multiple processing units 121. In the example of FIG. 1, the second transport part 122 transfers a substrate W to and from the first transport part 112 via a relay part 123. The relay part 123 may be a shelf on which the substrate W is placed or a shuttle-type transport part.

In the example of FIG. 1, the multiple (e.g., four) processing units 121 are provided so as to surround the second transport part 122 as seen in plan view. This second transport part 122 is referred to also as a center robot. The multiple processing units 121 may be disposed in vertically stacked relation in each position as seen in plan view. In other words, multiple (in FIG. 1, four) towers TW each comprised of the multiple processing units 121 disposed in vertically stacked relation may be provided so as to surround the second transport part 122.

In the example of FIG. 1, the multiple processing units 121 include at least one wet processing unit 121W and at least one dry processing unit 121D.

The wet processing unit 121W performs various wet processes on the substrate W. For example, the wet processing unit 121W performs a chemical liquid process for supplying a chemical liquid to a main surface of the substrate W and a rinsing process for supplying a rinsing liquid to the main surface of the substrate W in this order. A cleaning process and an etching process, for example, may be applied as the chemical liquid process. The wet processing unit 121W further performs a drying process for drying the substrate W after the rinsing process.

There are cases in which a pattern is formed on the main surface of the substrate W immediately before the transport into the wet processing unit 121W. In this case, the wet processing unit 121W may perform a hydrophobic process and the rinsing process in this order between the rinsing process and the drying process. The hydrophobic process is a process for supplying a hydrophobizing liquid such as a silylation liquid to the main surface of the substrate W to cause the hydrophobization of the main surface of the substrate W. Specifically, the hydrophobizing liquid acts on the main surface of the substrate W, whereby hydrophobic groups in the hydrophobizing liquid bond to the main surface of the substrate W, which in turn causes the hydrophobization of the main surface of the substrate W. The rinsing process after the hydrophobic process is a process for causing the rinsing liquid to wash away the hydrophobizing liquid. The hydrophobization of the substrate W reduces the surface tension of the rinsing liquid. This suppresses the collapse of the pattern in the subsequent drying process. In this case, organic matter (hydrophobic groups) is formed on the main surface of the substrate W after subjected to the drying process by means of the wet processing unit 121W. Such organic matter is removed by the dry processing unit 121D to be described later.

Alternatively, the wet processing unit 121W may perform a sublimation drying process as the drying process. Specifically, the wet processing unit 121W supplies a processing liquid containing a sublimable material to the main surface of the substrate W, dries the processing liquid to form a solidified film of the sublimable material, and then sublimates the solidified film to dry the substrate W. The sublimable material is organic matter, and is, for example, cyclohexanone oxime. In this case, organic matter (the sublimable material) can remain on the main surface of the substrate W after the drying process by means of the wet processing unit 121W. Such organic matter is removed by the dry processing unit 121D to be described later.

The dry processing unit 121D performs a dry process on the substrate W. Specifically, the dry processing unit 121D performs a process including any one of heating and supply of a processing gas on the substrate W. This process is also referred to hereinafter as a gas bake process. It is assumed herein that the dry processing unit 121D performs both the heating and the supply of the processing gas. As an example, the dry processing unit 121D supplies an oxidizing gas as the processing gas. The oxidizing gas is a gas which oxidizes the organic matter on the substrate W, and is, for example, ozone gas. Thus, the dry processing unit 121D oxidizes and removes the organic matter on the main surface of the substrate W.

In the example of FIG. 1, the dry processing unit 121D includes an electrostatic charging unit 20 and a gas bake unit 30 (corresponding to a processing unit). The electrostatic charging unit 20 positively charges the main surface of the substrate W. A specific example of the electrostatic charging unit 20 and functions thereof will be described in detail later. The gas bake unit 30 performs the gas bake process on the main surface of the substrate W which is positively charged. A specific example of the gas bake unit 30 will be described in detail later. In the example of FIG. 1, the dry processing unit 121D further includes a transport unit 40. The transport unit 40 transports the substrate W between the electrostatic charging unit 20 and the gas bake unit 30. It can be said that the transport unit 40 is a local transport unit. An example of the transport unit 40 will be described in detail later.

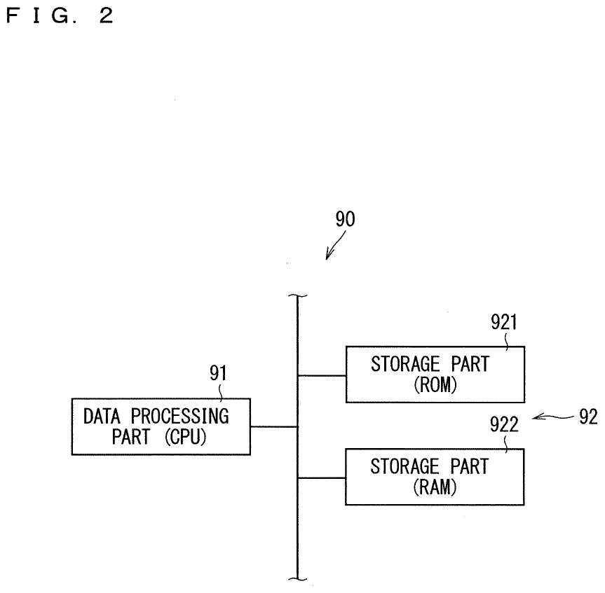

The controller 90 controls the substrate processing apparatus 100 in a centralized manner. More specifically, the controller 90 controls the first transport part 112, the second transport part 122, and the processing units 121. FIG. 2 is a block diagram schematically showing an example of the internal configuration of the controller 90. The controller 90 is an electronic circuit, and includes a data processing part 91 and a storage part 92, for example. The data processing part 91 and the storage part 92 are connectable to each other through a bus 93. The data processing part 91 may be, for example, an arithmetic processor such as a Central Processor Unit (CPU). The storage part 92 may include a non-temporary storage part 921 (for example, a Read Only Memory (ROM)) and a temporary storage part 922 (for example, a Random Access Memory (RAM)). A program for defining the processing that the controller 90 executes, for example, may be stored in the non-temporary storage medium 921. The data processing part 91 executes this program, whereby the controller 90 is able to execute the processing defined by the program. Of course, part or all of the processing that the controller 90 executes may be executed by a purpose-built logic circuit or other hardware.

### <Dry Processing Unit>

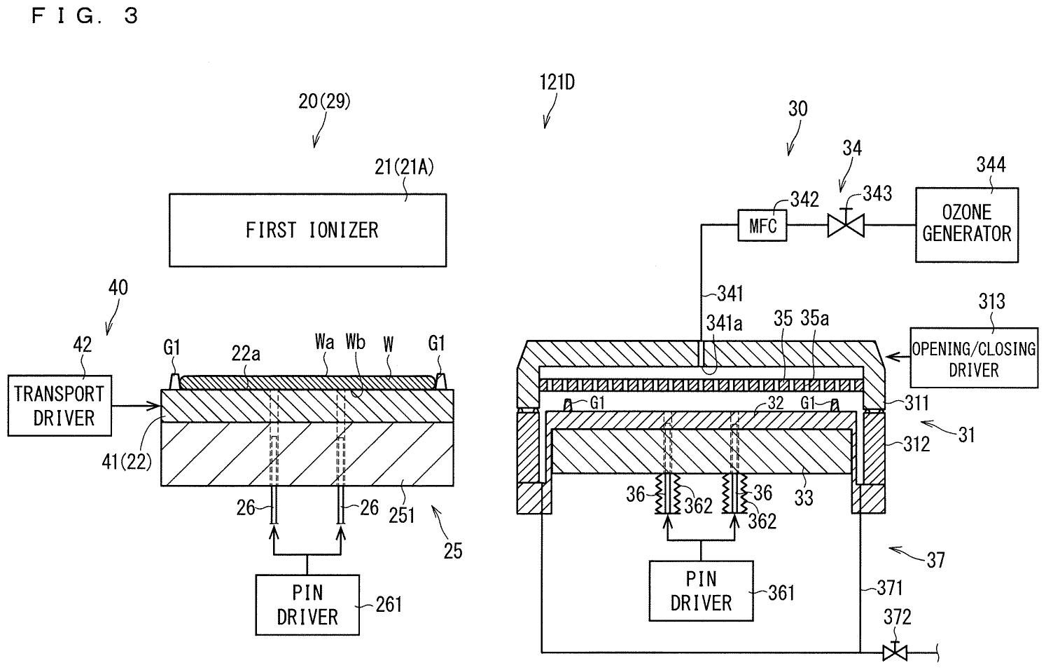

FIG. 3 is a view schematically showing an example of the configuration of the dry processing unit 121D. In the example of FIGS. 1 and 3, the electrostatic charging unit 20 is adjacent to the gas bake unit 30 in a horizontal direction. Both main surfaces of the substrate W are referred to hereinafter as a first main surface Wa and a second main surface Wb. The first main surface Wa and the second main surface Wb are opposite each other in the thickness direction of the substrate W. Organic matter such as hydrophobic groups, for example, is present on the first main surface Wa of the substrate W.

### <Electrostatic Charging Unit>

The electrostatic charging unit 20 positively charges the first main surface Wa of the substrate W. In the example of FIG. 3, the electrostatic charging unit 20 includes an electrostatic charger 21 and a substrate receiving part 22. The dry processing unit 121D may include a chamber not shown. The electrostatic charger 21 and the substrate receiving part 22 are provided in the chamber.

The substrate receiving part 22 supports or holds the substrate W in a horizontal attitude. The “horizontal attitude” used herein refers to an attitude in which the thickness direction of the substrate W extends in a vertical direction. The first main surface Wa (in this case, an upper surface) of the substrate W is exposed in the electrostatic charging unit 20 (in the chamber not shown). In the example of FIG. 3, the substrate receiving part 22 has a planar shape, and is provided in an attitude in which the thickness direction thereof extends in a vertical direction. In the example of FIG. 3, the substrate receiving part 22 has an upper surface 22a, and the upper surface 22a supports the second main surface Wb of the substrate W. It can be said that such a substrate receiving part 22 is a mounting table. The upper surface 22a of the substrate receiving part 22 may be wider than the substrate W as seen in plan view. The term “as seen in plan view” used herein means viewing an object in a vertical direction.

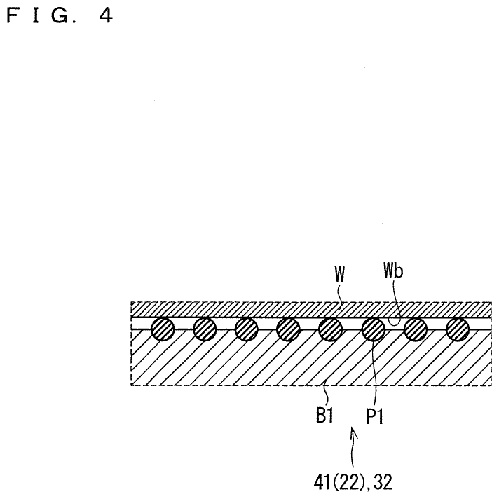

At least a contact portion of the substrate receiving part 22 which contacts the substrate W is made of an insulative material. FIG. 4 is a sectional view schematically showing an example of part of the configuration of the substrate receiving part 22. In the example of FIG. 4, the substrate receiving part 22 includes a main body plate B1 and multiple supporting elements P1. The main body plate B1 has a planar shape, and is provided in an attitude in which the thickness direction thereof extends in a vertical direction. In the example of FIG. 4, the supporting elements P1 are granular, and are dispersedly arranged on an upper surface of the main body plate B1. The supporting elements P1 protrude upwardly from the upper surface of the main body plate B1. The second main surface Wb of the substrate W is in contact with the multiple supporting elements P1, and is supported by the multiple supporting elements P1. In other words, the supporting elements P1 correspond to contact portions of the substrate receiving part 22 which contact the substrate W. In the example of FIG. 4, each of the supporting elements P1 has a spherical shape. In the example of FIG. 4, each of the supporting elements P1 has a lower portion buried in the main body plate B1, and an upper portion protruding from the main body plate B1. The amount of protrusion of the supporting elements P1 from the upper surface of the main body plate B1 may be, for example, not greater than 0.5 mm, and is approximately 0.1 mm as a specific example. The supporting elements P1 (contact portions) are made of an insulative material, for example, ceramics. The main body plate B1 may be made of an insulative material (ceramics or organic resin) or a conductive material such as metal, for example.

In the example of FIG. 3, the substrate receiving part 22 includes multiple positioning pins G1. The multiple positioning pins G1 are provided on the upper surface of the main body plate B1, and protrude upwardly from the upper surface of the main body plate B1. The multiple positioning pins G1 are provided in equally spaced relation along the periphery of the substrate W. The amount of protrusion of the positioning pins G1 is greater than that of the supporting elements P1, and may be greater than the thickness of the substrate W, for example. The positioning pins G1 abut against a side surface of the substrate W to determine the position of the substrate W as seen in plan view. The positioning pins G1 may be made of an insulative material. For example, the positioning pins G1 are made of ceramics or organic resin.

In the example of FIG. 3, the electrostatic charging unit 20 includes multiple (e.g., not less than three) elevating pins 26 and a pin driver 261. Each of the elevating pins 26 has an elongated shape extending in a vertical direction, and is provided so as to be able to vertically pass through the substrate receiving part 22 and a cooling plate 251 to be described later. The pin driver 261 is controlled by the controller 90, and moves the multiple elevating pins 26 upwardly and downwardly between a first upper pin position and a first lower pin position. The first upper pin position is a position in which the upper ends of the elevating pins 26 are above the upper surface 22a of the substrate receiving part 22, and the first lower pin position is a position in which the lower ends of the elevating pins 26 are below the upper surface 22a of the substrate receiving part 22. The pin driver 261 includes an air cylinder, for example. The elevating pins 26 move upwardly to the first upper pin position to thereby lift the substrate W from the substrate receiving part 22. At this time, the second main surface Wb of the substrate W abuts against the tips of the multiple elevating pins 26. With the multiple elevating pins 26 in the first upper pin position, the substrate W is transferred between the second transport part 122 and the elevating pins 26. The multiple elevating pins 26 move downwardly to the first lower pin position while supporting the substrate W, thereby allowing the substrate W to be passed to the substrate receiving part 22.

The electrostatic charger 21 is controlled by the controller 90, and positively charges the first main surface Wa of the substrate W placed on the substrate receiving part 22. In the example of FIG. 3, the electrostatic charger 21 includes a first ionizer 21A. The first ionizer 21A supplies cations to the first main surface Wa of the substrate W placed on the substrate receiving part 22 to positively charge the first main surface Wa of the substrate W. In the example of FIG. 3, the first ionizer 21A is provided above the substrate W placed on the substrate receiving part 22.

The first ionizer 21A is, for example, a corona discharge type ionizer for charging. For example, the first ionizer 21A includes an enclosure not shown and an electrode for discharge not shown. The electrode for discharge is provided in the enclosure. The first ionizer 21A causes a voltage to be applied to the electrode to produce a discharge, thereby generating cations. The enclosure has an outlet. The first ionizer 21A causes cations to flow out of the outlet of the enclosure toward the first main surface Wa of the substrate W. Although capable of producing electrons or anions (referred to hereinafter as “negative particles”), the first ionizer 21A causes sufficiently more cations than negative particles to flow out of the outlet. For example, a trapping electrode for capturing negative particles may be provided in the enclosure of the first ionizer 21A. The first ionizer 21A may further include a blower. The blower is, for example, a fan which causes carrier gas (e.g., air or nitrogen gas) to flow toward the outlet in the enclosure and to flow out of the outlet together with the cations.

The first ionizer 21A is capable of supplying cations to the entire first main surface Wa of the substrate W. This allows the entire first main surface Wa of the substrate W to be positively charged. The contact portions (e.g., the supporting elements P1 and the positioning pins G1) of the substrate receiving part 22 are insulated from the substrate W because the contact portions are made of an insulative material. This allows the substrate W on the substrate receiving part 22 to remain appropriately charged even after the first ionizer 21A stops supplying cations. The technical significance of positively charging the first main surface Wa of the substrate W will be described later. In the example of FIG. 3, the electrostatic charging unit 20 is provided with a cooler 25 which will be described later.

### <Transport Unit>

In the example of FIG. 3, the substrate receiving part 22 functions also as a transport plate 41 of the transport unit 40. The substrate receiving part 22 will be described hereinafter as the transport plate 41 in some cases. The transport unit 40 transports the substrate W between the electrostatic charging unit 20 and the gas bake unit 30, with the substrate W supported or held by the insulative contact portions (in this case, the supporting elements P1). For example, the transport unit 40 includes the transport plate 41 and a transport driver 42. The transport driver 42 moves the transport plate 41 in each of the horizontal and vertical directions, for example. In other words, the transport driver 42 includes a horizontal movement driver and an elevating driver. The transport driver 42 includes, for example, a drive source such as a motor, and a power transmission part for transmitting the drive power of the drive source to the transport plate 41. The power transmission part includes, for example, a ball screw mechanism. The transport driver 42 is controlled by the controller 90.

The transport driver 42 moves the transport plate 41 on which the substrate W after subjected to the charging process is placed toward the gas bake unit 30. This allows the transport unit 40 to transport the substrate W to the gas bake unit 30. The transport unit 40 is able to transport the substrate W while the substrate W remains charged because at least the contact portions (the supporting elements P1 and the positioning pins G1) of the transport plate 41 are insulated from the substrate W.

The gas bake unit 30 performs the gas bake process on the substrate W, which will be described in detail later. The transport unit 40 transports the substrate W after subjected to the gas bake process from the gas bake unit 30 to the electrostatic charging unit 20.

### <Gas Bake Unit (Processing Unit)>

The gas bake unit 30 includes a processing chamber 31. The interior space of the processing chamber 31 corresponds to a processing space in which the gas bake process is performed on the substrate W. In the example of FIG. 3, the processing chamber 31 has an opening/closing structure for the transport of the substrate W into and out of the processing chamber 31. As an example, the processing chamber 31 includes an upper member 311, a lower member 312, and an opening/closing driver 313. The upper member 311 is provided above the lower member 312. The opening/closing driver 313 switches between a closed state in which the upper member 311 and the lower member 312 are in contact with each other in a vertical direction and an open state in which the upper member 311 and the lower member 312 are separate from each other. In the closed state, the upper member 311 and the lower member 312 form an enclosed interior space. In the open state, the interior space is in communication with the outside where the transport unit 40 is present. In the example of FIG. 3, the opening/closing driver 313 moves the upper member 311 in a vertical direction. The opening/closing driver 313 may include, for example, a linear motion mechanism such as an air cylinder or a linear motor. Alternatively, the opening/closing driver 313 may include a motor and a power transmission part (e.g., a rack-and-pinion mechanism or a ball screw mechanism) which converts the rotation of the motor into linear movement.

The material of the processing chamber 31 may contain metal. As an example, stainless steel is applicable to the material of the processing chamber 31. Metal or metallic compounds (e.g., oxides) are exposed on at least part of inner walls of the processing chamber 31. The metal of the inner walls of the processing chamber 31 can flow out in an ionic state to the interior space of the processing chamber 31 by the gas bake process.

As shown in FIG. 3, the gas bake unit 30 includes a substrate receiving part 32. The substrate receiving part 32 supports or holds the substrate W in a horizontal attitude in the processing chamber 31. In the example of FIG. 3, the substrate receiving part 32 is formed by part of the lower member 312, and supports the second main surface Wb (in this case, a lower surface) of the substrate W. The first main surface Wa (in this case, the upper surface) of the substrate W is exposed in the processing chamber 31. In the example of FIG. 3, the substrate receiving part 32 has a planar shape, and is provided in an attitude in which the thickness direction thereof extends in a vertical direction. In the example of FIG. 3, the substrate receiving part 32 forms part of the bottom of the processing chamber 31, and the upper surface of the substrate receiving part 32 supports the second main surface Wb of the substrate W. It can be said that such a substrate receiving part 32 is a mounting table. In the example of FIG. 3, the upper surface of the substrate receiving part 32 is wider than the substrate W as seen in plan view.

At least a contact portion of the substrate receiving part 32 which contacts the substrate W is made of an insulative material. Like the substrate receiving part 22, the substrate receiving part 32 may include the main body plate B1 and the multiple supporting elements P1 (with reference to FIG. 4). Thus, the substrate receiving part 32 is capable of supporting or holding the substrate W while maintaining the charged state of the substrate W. As shown in FIG. 3, the substrate receiving part 32 may include the multiple positioning pins G1.

In the example of FIG. 3, the gas bake unit 30 includes multiple (e.g., not less than three) elevating pins 36 and a pin driver 361. Each of the elevating pins 36 has an elongated shape extending in a vertical direction, and is provided so as to be able to vertically pass through the substrate receiving part 32 and a heater 33 to be described later. The pin driver 361 is controlled by the controller 90, and moves the multiple elevating pins 36 upwardly and downwardly between a second upper pin position and a second lower pin position. The second upper pin position is a position in which the upper ends of the elevating pins 36 are above the upper surface of the substrate receiving part 32, and the second lower pin position is a position in which the lower ends of the elevating pins 36 are below the upper surface of the substrate receiving part 32. The pin driver 361 includes an air cylinder, for example. The multiple elevating pins 36 move upwardly to the second upper pin position to thereby lift the substrate W from the substrate receiving part 32. The multiple elevating pins 36 move downwardly to the second lower pin position, thereby allowing the substrate W to be passed to the substrate receiving part 32. With the multiple elevating pins 36 in the second upper pin position, the substrate W is transferred between the transport unit 40 and the elevating pins 36. At least the contact portions of the elevating pins 36 which contact the substrate W (i.e., the tips of the elevating pins 36) are made of an insulative material. For example, ceramics or organic resin is applied as the insulative material.

In the example of FIG. 3, the elevating pins 36 are provided with bellows 362. This maintains the hermeticity of the interior space of the processing chamber 31.

The gas bake unit 30 performs the gas bake process on the substrate W in the processing chamber 31. The gas bake process is a process including at least one of heating and supply of a processing gas on the substrate W. In the example of FIG. 3, the gas bake unit 30 includes the heater 33 and a processing gas supply part 34. That is, the gas bake unit 30 illustrated in FIG. 3 performs both the heating and the supply of the processing gas on the substrate W.

The heater 33 heats the substrate W placed on the substrate receiving part 32. The heater 33 is controlled by the controller 90, and heats the substrate W so that the temperature of the substrate W falls within a temperature range suitable for the gas bake process. The temperature is, for example, 100° C. or higher. The heater 33 is, for example, an electric resistance type heater or a radiant heater. As an example, the heater 33 includes a heat source such as a heating wire, and a heating plate. The heating plate is made of a material having a high thermal conductivity (e.g., aluminum or aluminum alloys). The heating plate has a planar shape, and is provided in an attitude in which the thickness direction thereof extends in a vertical direction. The heating plate has an upper surface abutting against the lower surface of the main body plate B1 of the substrate receiving part 32. The heat source is provided in the heating plate, and heats the heating plate. The heat generated by the heat source is transferred through the heating plate and the substrate receiving part 32 to the substrate W, so that the substrate W is heated.

The temperature of the processing chamber 31 also increases because the heat generated by the heater 33 is transferred to the processing chamber 31. This makes the processing chamber 31 relatively reactive. Thus, metal contained in the processing chamber 31 can flow out in an ionic state to the interior of the processing chamber 31 due to a reaction with the gas in the processing chamber 31. These metal ions are cations. The metal ions include, for example, at least one of manganese, iron, and copper ions.

The processing gas supply part 34 supplies the processing gas to the interior of the processing chamber 31. The processing gas acts on the first main surface Wa of the substrate W to perform a process in accordance with the type of processing gas on the first main surface Wa of the substrate W. The processing gas is, for example, an oxidizing gas. A specific example of the oxidizing gas includes ozone gas. In this case, the processing gas oxidizes and removes the organic matter on the first main surface Wa of the substrate W. The organic matter on the first main surface Wa of the substrate W is not particularly limited, but may be hydrophobic groups, for example. These hydrophobic groups can be formed on the first main surface Wa of the substrate W by the process in the wet processing unit 121W.

The processing gas supply part 34 includes a supply pipe 341, a pressure regulating part 342, a supply valve 343, and an ozone generator 344. The supply pipe 341 has a downstream end which is open in the processing chamber 31. The downstream end of the supply pipe 341 functions as a gas supply opening 341a. In the example of FIG. 3, the supply pipe 341 extends through the ceiling of the processing chamber 31, and the gas supply opening 341a is located in vertically opposed relation to a central portion of the substrate W. The supply pipe 341 has an upstream end connected to the ozone generator 344. The ozone generator 344 generates ozone gas which is an example of the processing gas. The ozone generation method using the ozone generator 344 is not particularly limited, but at least one of silent discharge, electrolysis, and ultraviolet lamp methods is applicable, for example. The ozone generator 344 supplies the ozone gas to the upstream end of the supply pipe 341.

The supply valve 343 is interposed in the supply pipe 341, and switches between the opening and closing of the supply pipe 341. When the supply valve 343 opens, the ozone gas from the ozone generator 344 flows through the interior of the supply pipe 341 toward the processing chamber 31, and flows into the interior space of the processing chamber 31. When the supply valve 343 closes, the supply of the ozone gas to the processing chamber 31 stops. The pressure regulating part 342 is, for example, an automatic pressure controller. The pressure regulating part 342 regulates the flow rate of the processing gas flowing through the supply pipe 341 so that the pressure in the processing chamber 31 is within a predetermined pressure range. The pressure regulating part 342 and the supply valve 343 are controlled by the controller 90.

The material of at least a longitudinal portion of the supply pipe 341 includes metal. For example, that portion of the supply pipe 341 is made of a stainless alloy. Metal or metallic compounds are exposed on the inner wall of that portion of the supply pipe 341. When the processing gas (e.g., ozone gas) acts on the inner wall of the supply pipe 341, metal ions can flow out into the interior of the supply pipe 341. The metal ions are cations, and include, for example, at least one of iron, manganese, and copper ions. The metal ions flow into the interior of the processing chamber 31 together with the processing gas.

In the example of FIG. 3, the gas bake unit 30 further includes a flow straightener 35. The flow straightener 35 has a planar shape, and is provided in an attitude in which the thickness direction thereof extends in a vertical direction. The flow straightener 35 is provided in vertically spaced apart relation to the gas supply opening 341a. The flow straightener 35 is also provided in vertically spaced apart relation to the substrate W, and in opposed relation to the substrate W. In other words, the flow straightener 35 is provided between the downstream end of the supply pipe 341 and the substrate W in the interior space of the processing chamber 31. The flow straightener 35 has a shape concentric with the substrate W as seen in plan view, for example, and has a diameter greater than that of the substrate W. The flow straightener 35 has multiple through holes 35a formed therein. The multiple through holes 35a are arranged two-dimensionally as seen in plan view, and are arranged in a matrix, for example. The multiple through holes 35a extend vertically through the flow straightener 35. In the example of FIG. 3, the flow straightener 35 is mounted to the upper member 311.

The gas flowing through the gas supply opening 341a of the supply pipe 341 into the interior space of the processing chamber 31 passes through the multiple through holes 35a of the flow straightener 35. The passage of the gas through the multiple through holes 35a causes the gas flow to straighten, so that the gas is more uniformly supplied to the first main surface Wa of the substrate W.

As shown in FIG. 3, the gas bake unit 30 further includes an exhaust part 37. The exhaust part 37 exhausts the gas in the processing chamber 31 to the outside. The exhaust part 37 includes an exhaust pipe 371 and an exhaust valve 372. In the example of FIG. 3, the exhaust pipe 371 has an upstream end connected to the bottom of the processing chamber 31. Specifically, the upstream end of the exhaust pipe 371 is connected to the lower member 312 in a location radially outside the substrate receiving part 32. The exhaust pipe 371 has a downstream end connected to an external exhaust part. The exhaust part may be a utility system in a factory. The exhaust valve 372 is controlled by the controller 90, and switches between the opening and closing of the exhaust pipe 371.

The ozone gas supplied through the supply pipe 341 into the processing chamber 31 reacts with the first main surface Wa of the substrate W to oxidize and remove the organic matter on the first main surface Wa of the substrate W. Reactances such as an organic gas and water vapor which are produced by this reaction are exhausted together with the ozone gas through the exhaust pipe 371 to the exhaust part outside the processing chamber 31.

In the gas bake process by means of the gas bake unit 30, metal ions can flow out of the inner walls of the processing chamber 31 and the supply pipe 341. This generates metal ions in the processing chamber 31. In other words, the gas bake process involves the generation of metal ions in the processing chamber 31. These metal ions can flow toward the first main surface Wa of the substrate W. However, the first main surface Wa of the substrate W is positively charged. For this reason, the metal ions repel the first main surface Wa of the substrate W. This reduces a likelihood that the substrate W is contaminated by metal.

As described above, the gas bake unit 30 is capable of performing the gas bake process on the substrate W while suppressing metal contamination.

In the aforementioned example, the substrate W is at high temperatures after the gas bake process because the gas bake unit 30 heats the substrate W. In the example of FIG. 3, the electrostatic charging unit 20 is provided with the cooler 25 for cooling the substrate W. Conversely, the electrostatic charging unit 20 (specifically, the electrostatic charger 21) is provided in a cooling unit 29 including the cooler 25.

In the example of FIG. 3, the cooler 25 includes the cooling plate 251. The cooling plate 251 has a planar shape, and is provided in an attitude in which the thickness direction thereof extends in a vertical direction. The cooling plate 251 has an upper surface abutting against the lower surface of the transport plate 41. The cooling plate 251 is made of a material having a high thermal conductivity (e.g., aluminum or aluminum alloys). The upper surface of the cooling plate 251 may be wider than the substrate W as seen in plan view. The cooler 25 includes a cooling source not shown for cooling the cooling plate 251. The cooling source includes, for example, an internal flow passage in the cooling plate 251 through which a refrigerant flows, refrigerant piping connected to the internal flow passage, and a heat pump unit provided in the refrigerant piping and for cooling the refrigerant. Alternatively, the cooling source may include a Peltier element provided in the cooling plate 251. The cooling source is controlled by the controller 90.

### <Example of Operation of Dry Processing Unit>

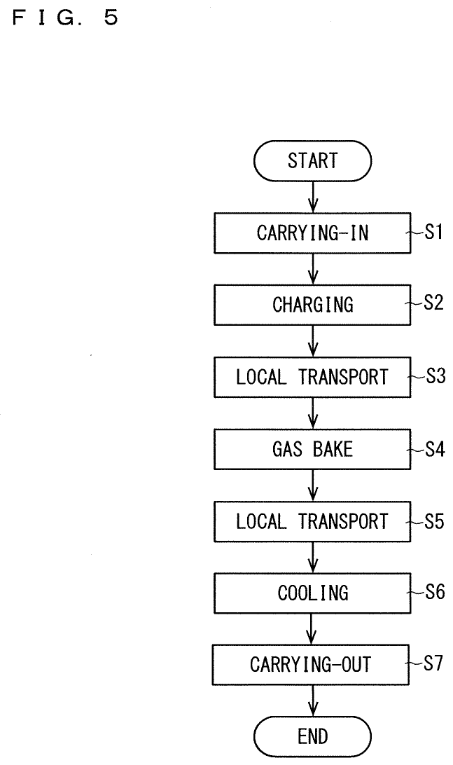

FIG. 5 is a flow diagram showing an example of the operation of the dry processing unit 121D. This flow diagram is executed by the controller 90 controlling the dry processing unit 121D in accordance with a predetermined procedure. First, the second transport part 122 transports the substrate W into the electrostatic charging unit 20 (Step S1: Carrying-in step). This places the substrate W on the transport plate 41. Organic matter is present on the first main surface Wa (in this case, the upper surface) of the substrate W. For example, hydrophobic groups (organic matter) are formed on the first main surface Wa of the substrate W by the hydrophobic process using the wet processing unit 121W.

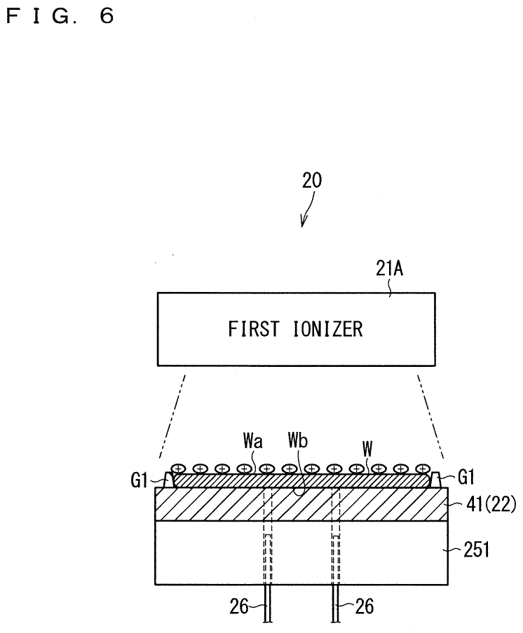

Next, the electrostatic charging unit 20 positively charges the first main surface Wa of the substrate W (Step S2: Charging step). FIG. 6 is a view schematically showing an example of the state of the electrostatic charging unit 20 in Step S2. The controller 90 puts the first ionizer 21A into operation. This causes the first ionizer 21A to generate cations, so that the cations flow out of the outlet toward the first main surface Wa of the substrate W. In the example of FIG. 6, the range of supply of cations of the first ionizer 21A is shown schematically in dash-double-dot lines, and the charged state of the first main surface Wa of the substrate W is schematically indicated by enclosed pluses (“+”).

In the example of FIG. 6, the cations flow in a spreading manner away from the first ionizer 21A, and are supplied to the entire first main surface Wa of the substrate W. Thus, the entire first main surface Wa of the substrate W is positively charged. After the first main surface Wa of the substrate W is sufficiently charged, the controller 90 stops the first ionizer 21A. As an example, the controller 90 stops the first ionizer 21A when a predetermined charging time period has elapsed since the start of the operation of the first ionizer 21A. The controller 90 measures the elapsed time period by means of a timer circuit not shown. The charging time period is set in advance so that the electric potential of the first main surface Wa of the substrate W is within a predetermined range. The minimum value in an electric potential distribution of the first main surface Wa of the substrate W after the charging process may be, for example, not less than 1V, not less than 5 V, not less than 10 V, or not less than 15 V. The maximum value in the electric potential distribution of the first main surface Wa of the substrate W after the charging process may be, for example, not greater than 50 V.

Next, the transport unit 40 transports the substrate W from the electrostatic charging unit 20 to the gas bake unit 30 (Step S3: Local transport step). The transport unit 40 is able to transport the substrate W to the gas bake unit 30 while the charged state of the substrate W is maintained because the contact portions of the transport plate 41 are made of an insulative material. As an example, the opening/closing driver 313 initially makes the processing chamber 31 open, and the transport unit 40 moves the substrate W to immediately over the elevating pins 36. The pin driver 361 moves the multiple elevating pins 36 upwardly to the second upper pin position. As a result, the substrate W is lifted by the multiple elevating pins 36. Then, the transport plate 41 moves to the outside of the processing chamber 31. The transport plate 41 is shaped not to collide with the elevating pins 36. Then, the pin driver 361 moves the multiple elevating pins 36 downwardly to the second lower pin position. As a result, the substrate W is placed on the substrate receiving part 32. The elevating pins 36 are able to place the substrate W on the substrate receiving part 32 while the charged state of the substrate W is maintained because the contact portions of the elevating pins 36 are made of an insulative material. Then, the opening/closing driver 313 makes the processing chamber 31 closed. The substrate receiving part 32 is able to support the substrate W while the charged state of the substrate W is maintained because the contact portions of the substrate receiving part 32 are made of an insulative material.

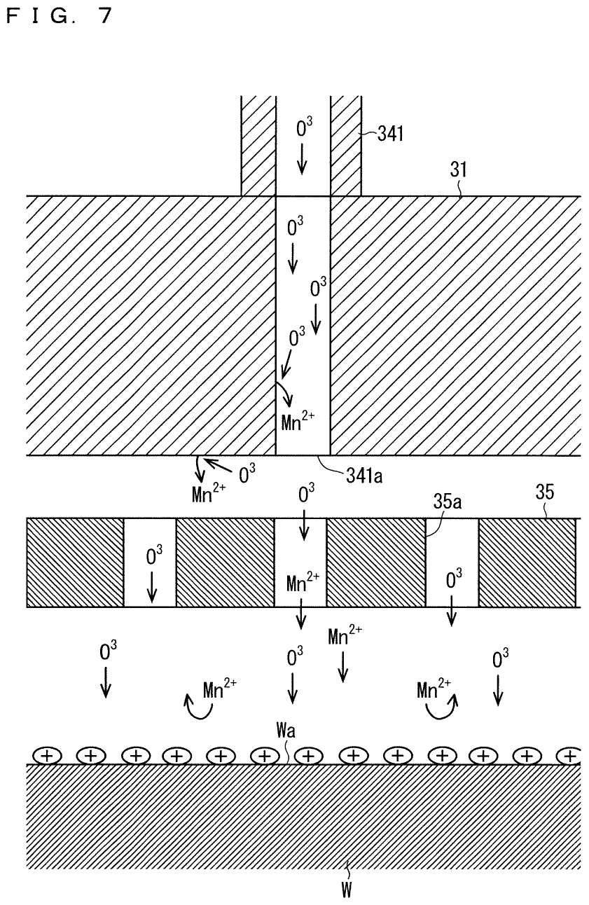

Next, the gas bake unit 30 supplies the processing gas (ozone gas) to the substrate W while heating the substrate W (Step S4: Gas bake step). Specifically, the controller 90 initially causes the heater 33 to heat the substrate W. When the temperature of the substrate W reaches a temperature suitable for the gas bake process, the controller 90 opens the supply valve 343 and the exhaust valve 372 while causing the ozone generator 344 to generate the ozone gas. As a result, the ozone gas flows through the supply pipe 341 into the processing chamber 31. FIG. 7 is an enlarged view showing an example of the state of the gas bake unit 30 in Step S4. The ozone gas acts on the inner wall of the supply pipe 341, whereby metal ions (manganese ions in FIG. 7) can flow out of the inner wall of the supply pipe 341. Also, the ozone gas acts on the inner wall of the processing chamber 31, whereby metal ions (manganese ions in FIG. 7) can flow out of the inner wall of the processing chamber 31. The ozone gas and the metal ions flow through the through holes 35a of the flow straightener 35 toward the first main surface Wa of the substrate W.

The ozone gas acts on the first main surface Wa of the substrate W to oxidize and remove organic matter on the first main surface Wa of the substrate W, and then flows into the exhaust pipe 371 together with reaction byproducts. On the other hand, the metal ions repel the positively charged first main surface Wa of the substrate W. Thus, the metal ions flow into the exhaust pipe 371 without coming too close to the first main surface Wa of the substrate W.

After the organic matter on the first main surface Wa of the substrate W is sufficiently removed, the controller 90 stops the heater 33 and the ozone generator 344, and closes the supply valve 343. As an example, when a predetermined processing time period has elapsed since the start of the supply of the ozone gas, the controller 90 stops the heater 33 and the ozone generator 344, and closes the supply valve 343. Next, the gas bake unit 30 may supply an inert gas such as nitrogen gas into the processing chamber 31 by means of an inert gas supply part not shown. This allows the ozone gas to be exhausted from the processing chamber 31.

Next, the transport unit 40 transports the substrate W from the gas bake unit 30 to the electrostatic charging unit 20 (Step S5: Local transport step). Specifically, the opening/closing driver 313 makes the processing chamber 31 open, and the elevating pins 36 lift the substrate W from the substrate receiving part 32. Then, the transport unit 40 receives the substrate W from the elevating pins 36, and moves the transport plate 41 onto the cooling plate 251.

Next, the electrostatic charging unit 20 cools the substrate W (Step S6: Cooling step). Specifically, the controller 90 puts the cooler 25 into operation. As a result, the substrate W is cooled. After the substrate W is sufficiently cooled, the controller 90 stops the cooler 25. As an example, when a predetermined cooling time period has elapsed since the start of the operation of the cooler 25, the controller 90 stops the cooler 25.

Next, the second transport part 122 transports the substrate W out of the electrostatic charging unit 20 (Step S7: Carrying-out step).

As described above, after the electrostatic charging unit 20 positively charges the first main surface Wa of the substrate W, the gas bake unit 30 performs the gas bake process on the substrate W. In other words, the gas bake unit 30 performs the gas bake process on the substrate W, with the first main surface Wa of the substrate W positively charged. The gas bake process is a process involving the generation of metal ions in the processing chamber 31. However, the metal ions, which are cations, repel the positively charged first main surface Wa of the substrate W. Thus, the gas bake unit 30 is capable of performing the gas bake process on the substrate W while reducing the likelihood that the substrate W is contaminated by metal.

In the aforementioned example, ozone gas is supplied as the processing gas. The ozone gas having high reactivity efficiently oxidizes and removes the organic matter on the first main surface Wa of the substrate W. On the other hand, the ozone gas having high reactivity increases the danger that metal ions flow out of the inner walls of the processing chamber 31 and the supply pipe 341. However, these metal ions repel the first main surface Wa of the substrate W. As a result, there is a low likelihood that metal contamination occurs when the organic matter is oxidized and removed.

In the aforementioned example, the electrostatic charger 21 includes the first ionizer 21A. The first ionizer 21A is capable of positively charging the first main surface Wa of the substrate W by supplying cations. This allows the substrate W to maintain the charged state even after the completion of the operation of the first ionizer 21A, as compared with an instance in which the substrate W is charged by induced polarization.

In the aforementioned example, the first ionizer 21A is provided outside the processing chamber 31. For this reason, even if metal is contained in the first ionizer 21A, the first ionizer 21A does not function as a metal source in the processing chamber 31. This further reduces the likelihood of the metal contamination of the substrate W.

In the aforementioned example, the dry processing unit 121D includes the electrostatic charging unit 20 and the gas bake unit 30. In other words, the electrostatic charging unit 20 and the gas bake unit 30 are provided in a one-to-one relationship. Thus, the dry processing unit 121D is capable of charging the substrate W in the electrostatic charging unit 20 immediately before the process in the gas bake unit 30 without causing a wait for the charging process. In other words, the gas bake unit 30 is able to perform the gas bake process immediately after the charging process using the electrostatic charging unit 20.

### Another Example

In the aforementioned example, the electrostatic charger 21 represented by the first ionizer 21A is provided outside the processing chamber 31. The present disclosure, however, is not limited to this. For example, the first ionizer 21A may be provided inside the processing chamber 31. Even in this case, after the electrostatic charging unit 20 performs the charging process on the substrate W in the processing chamber 31, the gas bake unit 30 performs the gas bake process on the substrate W in the processing chamber 31, with the substrate W charged. Thus, the gas bake unit 30 is capable of performing the gas bake process while reducing the likelihood of the metal contamination.

When the first ionizer 21A includes the blower, the first ionizer 21A may cause the carrier gas to flow out of the outlet in the gas bake process. In this case, the likelihood that the processing gas (ozone gas) in the processing chamber 31 enters the interior of the first ionizer 21A through the outlet is reduced. This, in turn, reduces the likelihood that the processing gas acts on a metal electrode in the first ionizer 21A. The metal electrode of the first ionizer 21A may be located far from the outlet. For example, the enclosure of the processing chamber 31 may be disposed so as to extend through the processing chamber 31, and the metal electrode may be provided outside the processing chamber 31. This further reduces the likelihood that the processing gas acts on the metal electrode.

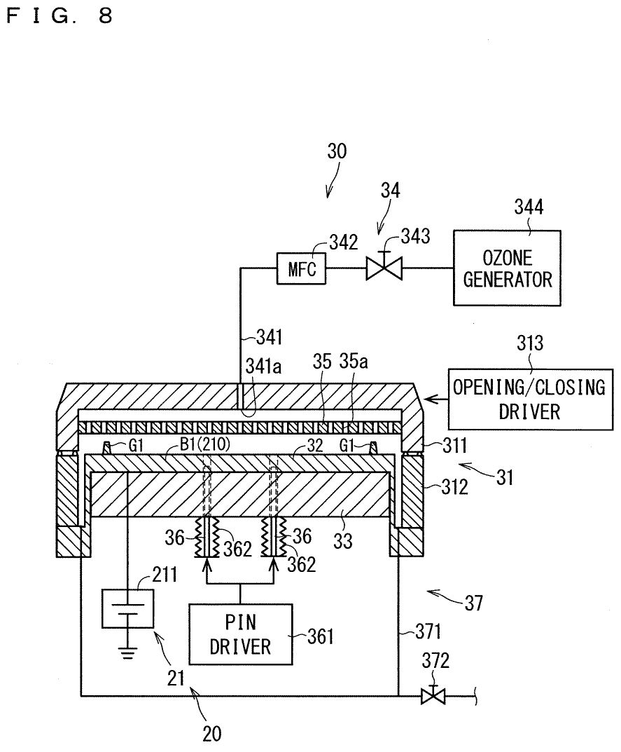

FIG. 8 is a view schematically showing another example of the configuration of the electrostatic charging unit 20. In the example of FIG. 8, the electrostatic charging unit 20 (the electrostatic charger 21) is provided in the gas bake unit 30. The electrostatic charging unit 20 applies an electric field (an electrostatic field) to the substrate W placed on the substrate receiving part 32 to positively charge the first main surface Wa of the substrate W. In the example of FIG. 8, the electrostatic charger 21 includes a conductor 210 and a power source 211. The conductor 210 is provided below the substrate W in the processing chamber 31. The conductor 210 may be, for example, the main body plate B1 of the substrate receiving part 32. The conductor 210 is made of metal, for example. The conductor 210 has a planar shape, and is provided in an attitude in which the thickness direction thereof extends in a vertical direction. The conductor 210 (in this case, the main body plate B1) faces the substrate W in vertically spaced apart relation (with reference to FIG. 4).

The power source 211 applies a positive potential to the conductor 210. The power source 211 is a DC power source, which has a positive terminal connected through wiring to the conductor 210 and a negative terminal grounded. The power source 211 is controlled by the controller 90.

When a positive potential is applied to the conductor 210, induced polarization occurs in the substrate W placed in the vicinity of the conductor 210. In other words, the second main surface Wb of the substrate W which faces the conductor 210 is negatively charged, and the first main surface Wa of the substrate W is positively charged.

The electrostatic charging unit 20 positively charges the first main surface Wa of the substrate W prior to the gas bake process. Specifically, the controller 90 causes the power source 211 to output voltage even prior to the gas bake process to positively charge the first main surface Wa of the substrate W. However, when the voltage output from the power source 211 is completed, the induced polarization of the substrate W disappears. For this reason, the controller 90 causes the power source 211 to maintain the voltage output in the gas bake process. This allows the gas bake unit 30 to perform the gas bake process on the substrate W while reducing the likelihood of the metal contamination. Although the controller 90 may maintain the voltage output from the power source 211 throughout the entire period of the gas bake process, the voltage output from the power source 211 may be maintained for only part of the period of the gas bake process. Even in this case, the likelihood of the metal contamination is reduced for the part of the period.

Unlike the example of FIG. 8, the electrostatic charging unit 20 may further include a conductive planar plate not shown. The planar plate and the conductor 210 vertically sandwich the substrate W therebetween. The conductive planar plate may be the ceiling of the processing chamber 31. In this case, the negative terminal of the power source 211 is connected through wiring to the planar plate. The same induced polarization as mentioned above occurs in the substrate W because an electric field is generated between the conductor 210 and the planar plate. Thus, the second main surface Wb of the substrate W is negatively charged, and the first main surface Wa of the substrate W is positively charged.

### Second Embodiment

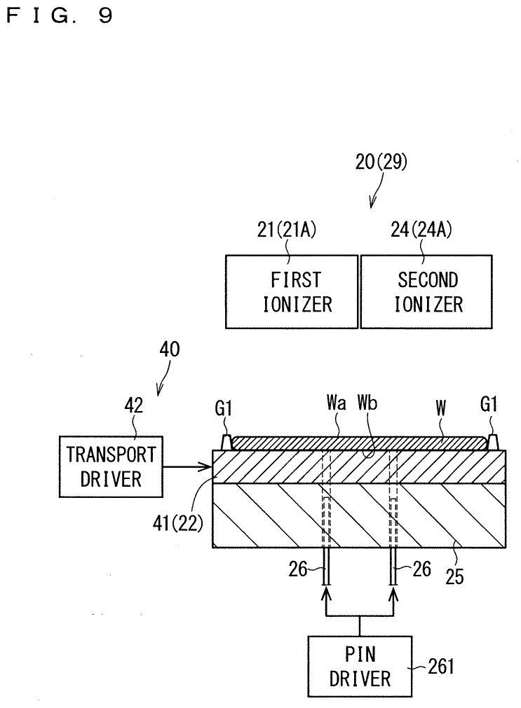

The substrate processing apparatus 100 according to a second embodiment differs in configuration of the electrostatic charging unit 20 from the substrate processing apparatus 100 according to the first embodiment. FIG. 9 is a view schematically showing an example of the configuration of the electrostatic charging unit 20 according to the second embodiment. In the second embodiment, the electrostatic charging unit 20 has not only the function of charging the substrate W but also the function of eliminating static from the substrate W.

In the example of FIG. 9, the electrostatic charging unit 20 further includes a static eliminator 24, as compared with the first embodiment. The static eliminator 24 eliminates static from the first main surface Wa of the substrate W. The static eliminator 24 includes, for example, a second ionizer 24A. The second ionizer 24A is an ionizer for eliminating static from the first main surface Wa of the substrate W. The second ionizer 24A is, for example, a corona discharge type ionizer. The second ionizer 24A supplies negative particles (e.g., electrons) to the first main surface Wa of the substrate W to eliminate static from the first main surface Wa of the substrate W. The second ionizer 24A may supply not only negative particles but also cations. For example, the second ionizer 24A may supply the same amounts of cations and negative particles to the first main surface Wa of the substrate W. Mainly negative particles (e.g., electrons) are attracted to the first main surface Wa of the substrate W to eliminate static from the first main surface Wa of the substrate W because the first main surface Wa of the substrate W is positively charged. That is, the second ionizer 24A is capable of eliminating static from the substrate W regardless of whether the substrate W is charged positively or negatively.

In the example of FIG. 9, the first ionizer 21A and the second ionizer 24A are provided above the substrate receiving part 22. The first ionizer 21A supplies cations, for example, to the entire first main surface Wa of the substrate W, and the second ionizer 24A supplies charged particles (including cations and negative particles), for example, to the entire first main surface Wa of the substrate W. The first ionizer 21A and the second ionizer 24A are controlled by the controller 90.

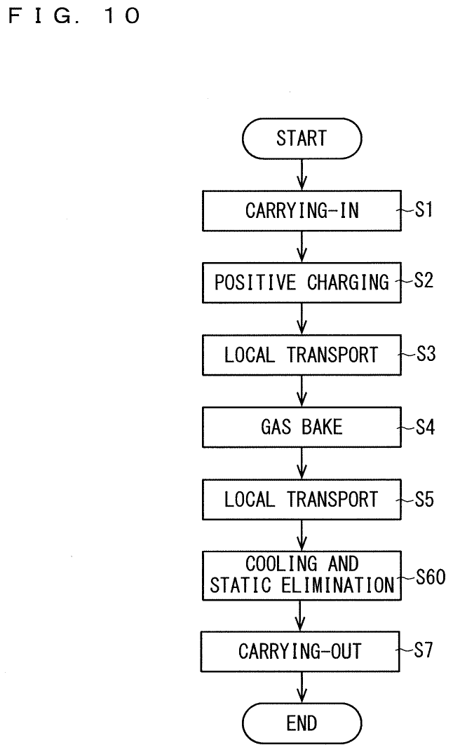

FIG. 10 is a flow diagram showing an example of the operation of the dry processing unit 121D according to the second embodiment. In the example of FIG. 10, Step S60 is executed in place of Step S6, as compared with FIG. 5. Step S60 is executed after Step S5. In Step S60, the electrostatic charging unit 20 eliminates static from the substrate W while cooling the substrate W (Cooling and static elimination step). Specifically, the controller 90 puts the second ionizer 24A into operation while operating the cooler 25. That is, the electrostatic charging unit 20 performs cooling and static elimination in parallel on the substrate W. In other words, the second ionizer 24A is put into operation during at least part of the cooling period for which the cooler 25 operates.

The controller 90 stops the second ionizer 24A when static is sufficiently eliminated from the first main surface Wa of the substrate W. For example, the controller 90 stops the second ionizer 24A when a predetermined static elimination time period has elapsed since the start of the operation of the second ionizer 24A. The static elimination time period is set in advance so that the electric potential of the first main surface Wa of the substrate W is sufficiently reduced. Then, when the cooling and static elimination of the substrate W are completed, the second transport part 122 transports the substrate W out of the dry processing unit 121D (Step S7).

As described above, after the gas bake process (Step S4) of the gas bake unit 30 is completed, the electrostatic charging unit 20 eliminates static from the substrate W (Step S60) in the second embodiment. For this reason, for example, the second transport part 122 transports the substrate W after the static elimination. This reduces the likelihood that particles adhere to the substrate W due to static electricity during the transport using the second transport part 122.

In addition, the electrostatic charging unit 20 performs the cooling and the static elimination in parallel on the substrate W in the aforementioned example. Thus, the electrostatic charging unit 20 performs the cooling and the static elimination on the substrate W at a higher throughput than when the cooling and the static elimination are performed at separate times.

### Third Embodiment

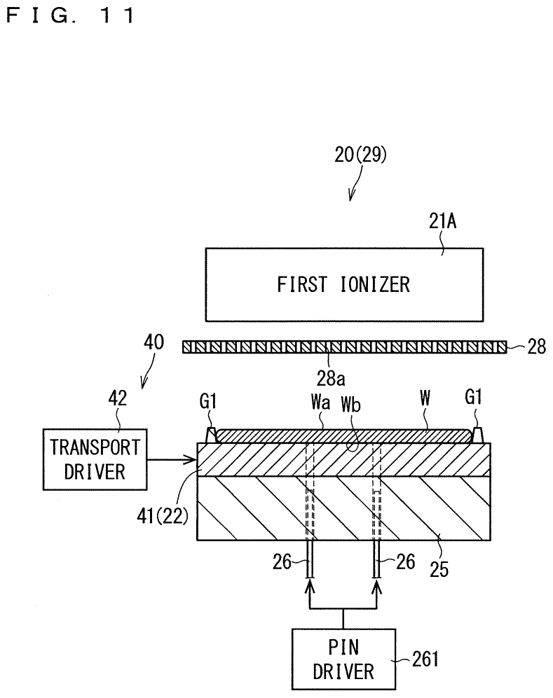

The substrate processing apparatus 100 according to a third embodiment differs in configuration of the electrostatic charging unit 20 from the substrate processing apparatus 100 according to the first embodiment. FIG. 11 is a view schematically showing an example of the configuration of the electrostatic charging unit 20 according to the third embodiment.

In the example of FIG. 11, the electrostatic charging unit 20 further includes a flow straightener 28, as compared with the first embodiment. The flow straightener 28 is provided between the outlet of the first ionizer 21A and the substrate receiving part 22. The flow straightener 28 has a planar shape, and is provided in an attitude in which the thickness direction thereof extends in a vertical direction. The flow straightener 28 is provided in vertically spaced apart relation to the outlet of the first ionizer 21A. The flow straightener 28 is also provided in vertically spaced apart relation to the substrate W, and in opposed relation to the substrate W. The flow straightener 28 has, for example, a shape wider than the substrate W as seen in plan view. The flow straightener 28 has multiple through holes 28a formed therein. The multiple through holes 28a are arranged two-dimensionally as seen in plan view, and are arranged in a matrix, for example. The multiple through holes 28a extend vertically through the flow straightener 28. The flow straightener 28 is made of an insulative material, for example. For example, the flow straightener 28 is made of organic resin or ceramics.

According to the third embodiment, the cations flowing out of the outlet of the first ionizer 21A flow through the multiple through holes 28a of the flow straightener 28 toward the first main surface Wa of the substrate W. This allows the cations to be supplied more uniformly to the first main surface Wa of the substrate W. Thus, the electrostatic charging unit 20 is capable of charging the first main surface Wa of the substrate W with higher uniformity. In other words, the electrostatic charging unit 20 is capable of making the potential distribution of the first main surface Wa of the substrate W more uniform after the charging process.

### Fourth Embodiment

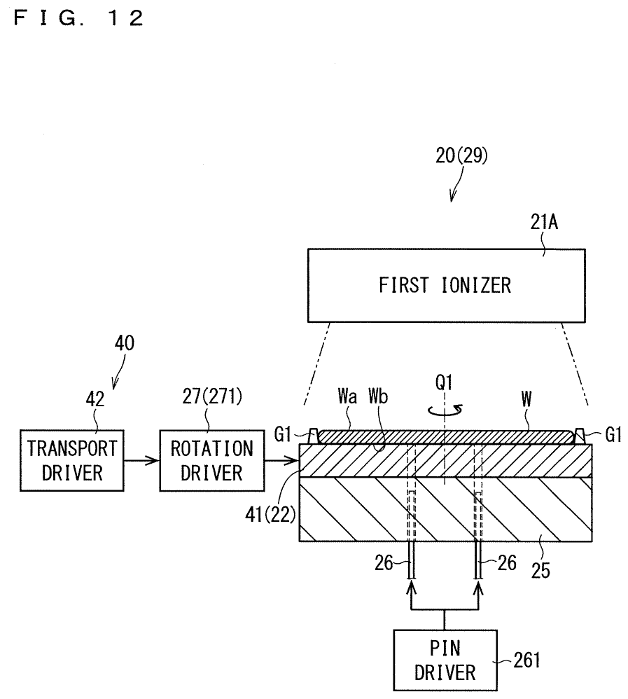

The substrate processing apparatus 100 according to a fourth embodiment differs in configuration of the electrostatic charging unit 20 from the substrate processing apparatus 100 according to the first embodiment. FIG. 12 is a view schematically showing a first example of the configuration of the electrostatic charging unit 20 according to the fourth embodiment.

In the example of FIG. 12, the electrostatic charging unit 20 further includes a displacement driver 27, as compared with the first embodiment. The displacement driver 27 changes the relative positional relationship between the substrate W placed on the substrate receiving part 22 and the first ionizer 21A. Specifically, the displacement driver 27 moves one of the first ionizer 21A and the substrate W relative to the other. As a result, the supply range of cations of the first ionizer 21A moves relative to the first main surface Wa of the substrate W. Thus, the electrostatic charging unit 20 is capable of supplying cations more uniformly to the first main surface Wa of the substrate W. Specific examples of the displacement driver 27 will be described below.

In the example of FIG. 12, the displacement driver 27 includes a rotation driver 271. The rotation driver 271 rotates the substrate W about a rotational axis Q1. The rotational axis Q1 is an axis passing through the center of the substrate W on the transport plate 41 and extending in a vertical direction. In the example of FIG. 12, the rotation driver 271 rotates the transport plate 41 about the rotational axis Q1. As a result, the substrate W supported by the transport plate 41 also rotates about the rotational axis Q1.

The rotation driver 271 includes a drive source such as a motor, and a power transmission part for transmitting the drive power of the drive source to the transport plate 41. The power transmission part includes a shaft. The power transmission part may include gears or a belt. The rotation driver 271 is controlled by the controller 90.

The transport driver 42 may be connected to the rotation driver 271, and may move the rotation driver 271 and the transport plate 41 integrally. With the transport driver 42 moving the transport plate 41 upwardly and separating the transport plate 41 upwardly from the cooling plate 251, the rotation driver 271 may rotate the transport plate 41 and the substrate W integrally.

An example of the operation of the dry processing unit 121D according to the fourth embodiment is the same as that shown in FIG. 5 except that the controller 90 puts the first ionizer 21A into operation while driving the displacement driver 27 (e.g., the rotation driver 271) in Step S2. That is, the rotation driver 271 rotates the substrate W during at least part of the charging time period for which the first ionizer 21A supplies cations to the substrate W. The rotation driver 271 may continue operating throughout the entire charging time period. This holds true for other specific examples of the displacement driver 27 which will be discussed below.

The supply range of cations by means of the first ionizer 21A may be equal in size to or greater in size than the entire first main surface Wa of the substrate W. In this case, even if there are variations in the distribution of the cations within the supply range, the electrostatic charging unit 20 supplies the cations more uniformly to the first main surface Wa of the substrate W. This holds true for other specific examples of the displacement driver 27 which will be discussed below.

On the other hand, the supply range of cations may be smaller in size than the first main surface Wa of the substrate W. Specifically, the supply range may be an elongated range which is not less than the radius of the substrate W which includes the center and the periphery thereof. As the substrate W rotates, the supply range passes over the entire first main surface Wa of the substrate W, so that the electrostatic charging unit 20 is able to supply the cations to the entire first main surface Wa of the substrate W. According to this structure, the first ionizer 21A which is smaller in size may be employed.

In the aforementioned example, the rotation driver 271 rotates the substrate W. The present disclosure, however, is not limited to this. The rotation driver 271 may rotate the first ionizer 21A about the rotational axis Q1. In short, it is sufficient that the rotation driver 271 rotates one of the first ionizer 21A and the substrate W relative to the other about the rotational axis Q1.

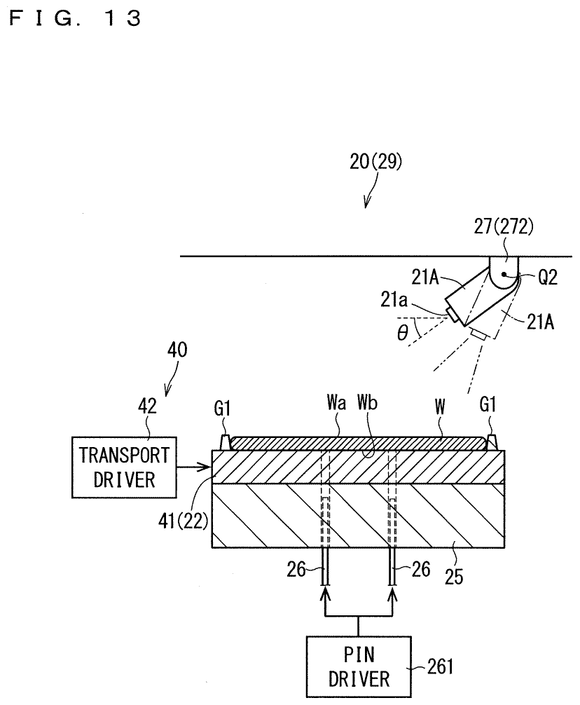

FIG. 13 is a view schematically showing a second example of the configuration of the electrostatic charging unit 20 according to the fourth embodiment. In the example of FIG. 13, the displacement driver 27 includes a pivot driver 272. The pivot driver 272 rotates (i.e., pivots) the first ionizer 21A in forward and reverse directions within a predetermined angular range about a rotational axis Q2. The rotational axis Q2 is an axis extending in a horizontal direction, and, in the example of FIG. 13, is an axis extending in a direction perpendicular to the plane of FIG. 13. In the example of FIG. 13, the first ionizer 21A being rotated is shown schematically in dot-dash lines.

The pivot driver 272 includes a drive source such as a motor, and a power transmission part for transmitting the drive power of the drive source to the first ionizer 21A. The power transmission part includes a shaft. The power transmission part may include gears or a belt. The pivot driver 272 is provided, for example, on the ceiling of a chamber (not shown) of the electrostatic charging unit 20.

In the example of FIG. 13, the horizontal position of the first ionizer 21A is shifted from the center of the substrate W. Specifically, the first ionizer 21A is located off the center of the substrate W in a horizontal direction orthogonal to the rotational axis Q2.

The first ionizer 21A may have an elongated shape extending along the rotational axis Q2. In other words, the longitudinal direction of the first ionizer 21A may extend along the rotational axis Q2. The first ionizer 21A has an outlet 21a for causing cations to flow out in an obliquely downward direction. The pivot driver 272 rotates the first ionizer 21A about the rotational axis Q2, which in turn changes the depression angle θ of the first ionizer 21A. As a result, the supply range of cations by means of the first ionizer 21A moves relative to the first main surface Wa of the substrate W.

In Step S2, the controller 90 puts the first ionizer 21A into operation while driving the pivot driver 272. That is, the pivot driver 272 rotates the first ionizer 21A within a predetermined angular range during at least part of the charging time period. The pivot driver 272 may rotate the first ionizer 21A in one direction within a predetermined angular range or may reciprocate (pivot) the first ionizer 21A within a predetermined angular range.

The supply range of cations by means of the first ionizer 21A may be smaller in size than the first main surface Wa of the substrate W. Specifically, the supply range may be an elongated range having a longitudinal direction parallel to the rotational axis Q2. The length of the elongated range in the longitudinal direction is not less than the diameter of the substrate W. The pivot driver 272 rotates the first ionizer 21A, which in turn moves the supply range in a horizontal direction orthogonal to the rotational axis Q2 on the first main surface Wa of the substrate W. The angular range of the pivot driver 272 is set in advance to the extent that the supply range of cations passes over the entire first main surface Wa of the substrate W. This allows the electrostatic charging unit 20 to appropriately charge the entire first main surface Wa of the substrate W. In addition, the first ionizer 21A which is smaller in size may be employed.

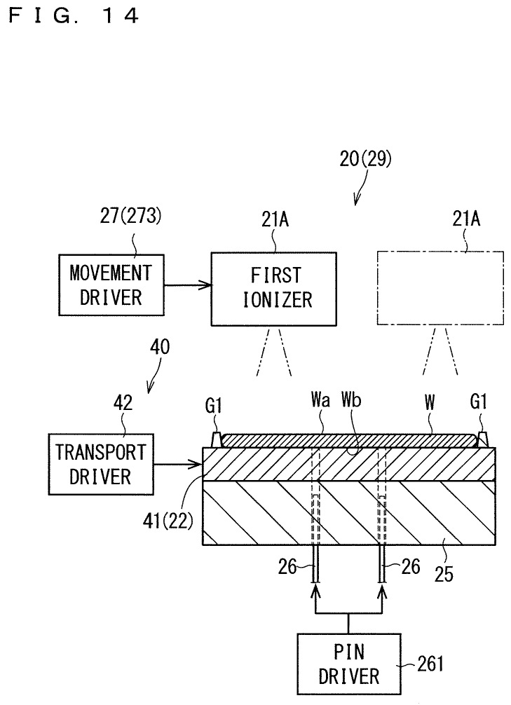

FIG. 14 is a view schematically showing a third example of the configuration of the electrostatic charging unit 20 according to the fourth embodiment. In the example of FIG. 14, the displacement driver 27 includes a movement driver 273. The movement driver 273 moves the first ionizer 21A in a direction (in this case, in a horizontal direction) along the first main surface Wa of the substrate W. The movement driver 273 may move the first ionizer 21A back and forth within a predetermined movement range. In the example of FIG. 14, the first ionizer 21A being moved is shown schematically in dot-dash lines. The movement driver 273 includes, for example, a drive source such as a motor, and a power transmission part for transmitting the drive power of the drive source to the first ionizer 21A. The power transmission part includes, for example, a ball screw mechanism.

The movement driver 273 moves the first ionizer 21A horizontally, which in turn moves the supply range of cations horizontally relative to the first main surface Wa of the substrate W.

In Step S2, the controller 90 puts the first ionizer 21A into operation while causing the movement driver 273 to move the first ionizer 21A. The movement driver 273 may move the first ionizer 21A in one direction within a predetermined movement range during the charging time period or may reciprocate the first ionizer 21A within a predetermined movement range.

The supply range of cations by means of the first ionizer 21A may be smaller in size than the first main surface Wa of the substrate W. Specifically, the supply range may be an elongated range having a longitudinal direction orthogonal to the movement direction of the movement driver 273. The length of the elongated range in the longitudinal direction is not less than the diameter of the substrate W. The movement driver 273 moves the first ionizer 21A horizontally, which in turn moves the supply range in the movement direction on the first main surface Wa of the substrate W. The movement range of the movement driver 273 is set in advance so that the supply range passes over the entire first main surface Wa of the substrate W. This allows the electrostatic charging unit 20 to appropriately charge the entire first main surface Wa of the substrate W. In addition, the first ionizer 21A which is smaller in size may be employed.

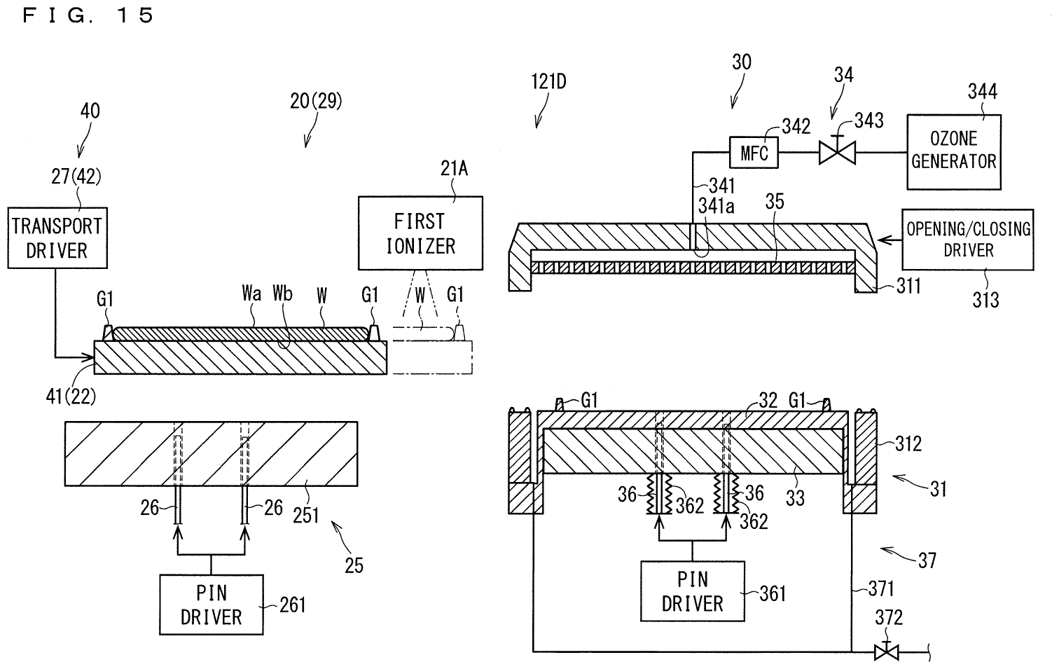

FIG. 15 is a view schematically showing a fourth example of the configuration of the electrostatic charging unit 20 according to the fourth embodiment. In the example of FIG. 15, the displacement driver 27 includes the transport driver 42. The transport driver 42 moves the transport plate 41 and the substrate W integrally in a direction (in this case, in a horizontal direction) along the first main surface Wa of the substrate W.

The first ionizer 21A is provided in a position to be described below. That is, the first ionizer 21A is provided in a position where the first main surface Wa of the substrate W is able to cross the supply range of the first ionizer 21A when the transport unit 40 transports the substrate W to the gas bake unit 30. In other words, the first ionizer 21A supplies cations to a portion of a transport path of the substrate W. The term “transport path” used herein refers to a trajectory of the substrate W moving between the electrostatic charging unit 20 and the gas bake unit 30. The first ionizer 21A may be provided in a position where the first ionizer 21A is able to supply cations to a portion of the transport path which extends horizontally. As shown in FIG. 15, the first ionizer 21A may be provided above the transport path and in a position vertically opposed to the transport path. In the example of FIG. 15, the first ionizer 21A is located between the cooling plate 251 and the processing chamber 31 as seen in plan view.

The supply range of cations by means of the first ionizer 21A may be smaller in size than the first main surface Wa of the substrate W. The supply range may be an elongated range having a longitudinal direction perpendicular to the plane of FIG. 15. In other words, the supply range may be an elongated range having a longitudinal direction parallel to the width direction of the portion of the transport path which extends horizontally. The length of the elongated range in the longitudinal direction is not less than the diameter of the substrate W. The transport driver 42 moves the transport plate 41 and the substrate W horizontally, whereby the substrate W crosses directly under the first ionizer 21A. In the example of FIG. 15, parts of the transport plate 41 and the substrate W being transported are shown schematically in dash-dot lines. This movement supplies cations to the entire first main surface Wa of the substrate W. This allows the electrostatic charging unit 20 to appropriately charge the entire first main surface Wa of the substrate W. In addition, the first ionizer 21A which is smaller in size may be employed.

In the fourth example of the fourth embodiment, Steps S2 and S3 are executed in parallel. That is, the controller 90 puts the first ionizer 21A into operation while causing the transport driver 42 to move the transport plate 41 and the substrate W integrally.

The transport driver 42 may move the transport plate 41 and the substrate W to cause the transport plate 41 and the substrate W to pass directly under the first ionizer 21A only once or may move the transport plate 41 and the substrate W back and forth within a predetermined movement range directly under the first ionizer 21A. The predetermined movement range is set in advance so that the supply range passes over the entire first main surface Wa of the substrate W.

The fourth embodiment may be applied to the second ionizer 24A of the second embodiment. That is, a displacement driver (not shown) for changing the relative positional relationship between the substrate W and the second ionizer 24A may be provided. This displacement driver may be the same as the displacement driver 27 described above.

### Fifth Embodiment

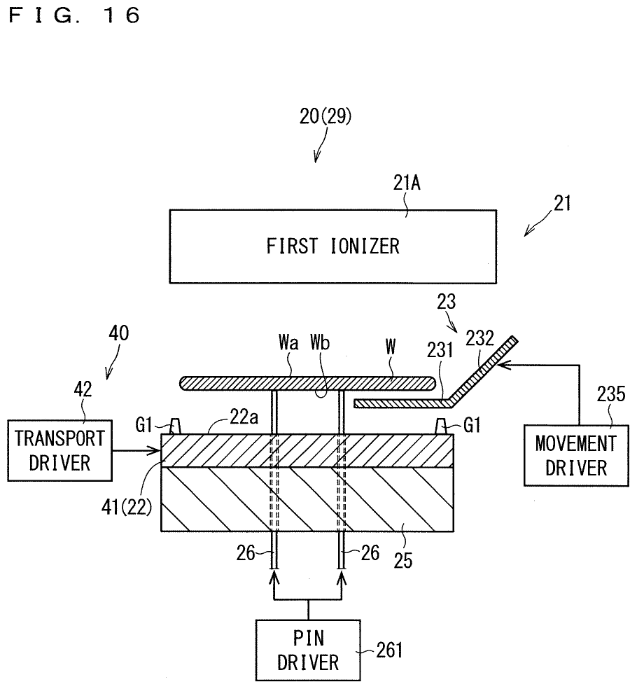

The substrate processing apparatus 100 according to a fifth embodiment differs in configuration of the electrostatic charging unit 20 from the substrate processing apparatus 100 according to the first embodiment. FIG. 16 is a view schematically showing a first example of the configuration of the electrostatic charging unit 20 according to the fifth embodiment.

In the fifth embodiment, the electrostatic charger 21 of the electrostatic charging unit 20 positively charges both the first and second main surfaces Wa and Wb of the substrate W. In the example of FIG. 16, the multiple elevating pins 26 are in the first upper pin position and support the substrate W. In this state, the entire first main surface Wa and most of the second main surface Wb of the substrate W are exposed in the electrostatic charging unit 20 (in the chamber not shown). In this state, the electrostatic charger 21 positively charges the first and second main surfaces Wa and Wb of the substrate W.

In the example of FIG. 16, the electrostatic charger 21 includes the first ionizer 21A, a guiding member 23, and a movement driver 235. The guiding member 23 is a member for guiding cations from the first ionizer 21A to the second main surface Wb of the substrate W. The guiding member 23 is made of an insulative material, for example. For example, ceramics or organic resin is applied as the insulative material. The movement driver 235 moves the guiding member 23 between a charging position and a standby position both to be described below, with the multiple elevating pins 26 supporting the substrate W in the first upper pin position. The charging position is a position in which part of the guiding member 23 is interposed between the second main surface Wb of the substrate W and the substrate receiving part 32, and in which the part of the guiding member 23 faces the second main surface Wb of the substrate W in spaced apart relation. In the example of FIG. 16, the guiding member 23 is shown as stopped in the charging position. While located in the charging position, the guiding member 23 guides the cations from the first ionizer 21A to the second main surface Wb of the substrate W. The standby position is a position in which the guiding member 23 does not face the substrate W in a vertical direction, and, for example, a position outside the substrate W in a radial direction. The standby position is a position in which the guiding member 23 does not interfere with the transport path of the substrate W. The movement driver 235 includes, for example, a drive source such as a motor, and a power transmission part for transmitting the drive power of the drive source to the guiding member 23. The power transmission part includes, for example, a ball screw mechanism.

In the example of FIG. 16, the guiding member 23 includes a facing portion 231 and an inclined portion 232. The facing portion 231 is a portion partially facing the second main surface Wb of the substrate W when the guiding member 23 is in the charging position. In other words, the facing portion 231 is located partially between the substrate W and the transport plate 41. A surface (in this case, an upper surface) of the facing portion 231 which faces the second main surface Wb of the substrate W is, for example, a horizontal flat surface. The facing portion 231 has, for example, a planar shape, and is provided in an attitude in which the thickness direction thereof extends in a vertical direction. The facing portion 231 faces the second main surface Wb of the substrate W in a region which does not collide with the multiple elevating pins 26. That is, the facing portion 231 does not contact the elevating pins 26. The facing portion 231 extends outwardly from the substrate W as seen in plan view when the guiding member 23 is in the charging position. The facing portion 231 may have, for example, a rectangular shape as seen in plan view.

The inclined portion 232 extends from an end portion of the facing portion 231 which extends outwardly from the substrate W. The inclined portion 232 has an upper surface inclined as seen in a horizontal direction away from the substrate W in an upward direction. The inclined portion 232 is located outside the substrate W when the guiding member 23 is in the charging position. The inclined portion 232 has an upper end located above the first main surface Wa of the substrate W. The upper end of the inclined portion 232 can be located below the first ionizer 21A. In the example of FIG. 16, the inclined portion 232 has a planar shape. The inclined portion 232 may have, for example, a rectangular shape as seen in plan view.

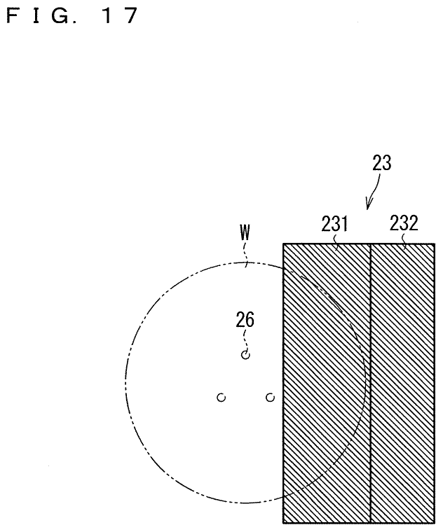

The guiding member 23 may have an elongated shape extending in a direction perpendicular to the plane of FIG. 16. FIG. 17 is a plan view schematically showing an example of the configuration of the guiding member 23. In the example of FIG. 17, the facing portion 231 is adjacent to the inclined portion 232 in a right-and-left direction as seen in the plane of FIG. 17, and the longitudinal direction of the guiding member 23 extends in an up-and-down direction as seen in the plane of FIG. 17. In other words, the longitudinal direction of the guiding member 23 is a direction perpendicular to the direction in which the facing portion 231 and the inclined portion 232 are adjacent to each other. The length of the guiding member 23 in the longitudinal direction is not less than the diameter of the substrate W.

As shown in FIG. 16, the first ionizer 21A supplies cations to the first main surface Wa of the substrate W and to a portion outside the first main surface Wa of the substrate W (specifically, the upper surface of the guiding member 23). For example, the supply range of cations by means of the first ionizer 21A as seen in plan view covers both the first main surface Wa of the substrate W and the upper surface of the guiding member 23. The first ionizer 21A causes the cations and the carrier gas to flow out toward the substrate W and the guiding member 23. The cations are supplied to the first main surface Wa of the substrate W, whereby the first main surface Wa of the substrate W is positively charged.

On the other hand, the carrier gas and cations flowing to the portion outside the first main surface Wa of the substrate W are supplied to the upper surface of the guiding member 23. The cations supplied to the upper surface of the guiding member 23 flow along the upper surface of the guiding member 23 together with the carrier gas, and flow between the facing portion 231 and the second main surface Wb of the substrate W. That is, the cations are guided to the second main surface Wb of the substrate W. The cations flow between the second main surface Wb of the substrate W and the facing portion 231 and thereafter flow between the second main surface Wb of the substrate W and the upper surface 22a of the transport plate 41. This causes the cations to act on the entire second main surface Wb of the substrate W, so that the second main surface Wb of the substrate W is also positively charged.

The distance between the upper surface of the facing portion 231 and the second main surface Wb of the substrate W is smaller than the distance between the upper surface 22a of the transport plate 41 and the second main surface Wb of the substrate W. The distance between the transport plate 41 and the substrate W may be set to not greater than 50 mm, to not greater than 30 mm, or to not greater than 10 mm. This facilitates the supply of the cations to the second main surface Wb of the substrate W.

An example of the operation of the dry processing unit 121D according to the fifth embodiment is the same as that shown in FIG. 5 except that the controller 90 causes the movement driver 235 to move the guiding member 23 to the charging position in Step S2, with the substrate W supported by the multiple elevating pins 26. For example, the elevating pins 26 in the first upper pin position receive the substrate W from the second transport part 122. Thus, the substrate W is supported by the elevating pins 26. Next, the controller 90 causes the movement driver 235 to move the guiding member 23 to the charging position. Next, the controller 90 puts the first ionizer 21A into operation. The first ionizer 21A supplies cations to both the first main surface Wa of the substrate W and the upper surface of the guiding member 23. As a result, both the first and second main surfaces Wa and Wb of the substrate W are positively charged as described above.

After both the first and second main surfaces Wa and Wb of the substrate W are sufficiently positively charged, the controller 90 stops the first ionizer 21A, causes the movement driver 235 to move the guiding member 23 to the standby position, and causes the pin driver 261 to move the elevating pins 26 downwardly. Thus, the substrate W having the positively charged first and second main surfaces Wa and Wb is placed on the transport plate 41.

Next, the transport unit 40 transports the substrate W to the gas bake unit 30 while maintaining the charged state of the substrate W, and the substrate receiving part 32 of the gas bake unit 30 supports the substrate W while maintaining the charged state of the substrate W (Step S3). Specifically, the substrate receiving part 32 supports the second main surface Wb of the substrate W by means of the multiple supporting elements P1 protruding from the upper surface of the main body plate B1. Thus, the upper surface of the main body plate B1 corresponds to an opposed surface which faces the second main surface Wb of the substrate W in spaced apart relation. In other words, a gap is formed between the second main surface Wb of the substrate W and the main body plate B1 (with reference to FIG. 4).

Next, the gas bake unit 30 performs the gas bake process (Step S4). In this gas bake process, there is a danger that metal ions in the processing chamber 31 flow into the gap between the second main surface Wb of the substrate W and the main body plate B1. However, the metal ions repel the second main surface Wb of the substrate W because the second main surface Wb of the substrate W is positively charged. This reduces the likelihood that the second main surface Wb of the substrate W is contaminated by metal. Thereafter, Steps S5 to S7 are executed in this order.

In the fifth embodiment, as described above, the electrostatic charging unit 20 positively charges the first main surface Wa and the second main surface Wb of the substrate W, and the gas bake unit 30 performs the gas bake process, with the substrate W maintained in the charged state. This allows the gas bake unit 30 to perform the gas bake process on the substrate W while suppressing metal contamination of both the first main surface Wa and the second main surface Wb of the substrate W.

In the aforementioned example, the substrate receiving part 22 for supporting the second main surface Wb of the substrate W is provided. In this state, it is difficult to supply cations to the second main surface Wb of the substrate W. In the aforementioned example, however, the first ionizer 21A supplies cations while the elevating pins 26 lift the substrate W and the guiding member 23 is moved to the charging position. Thus, the electrostatic charging unit 20 appropriately positively charges the first main surface Wa and the second main surface Wb of the substrate W.

In the aforementioned example, both the first main surface Wa of the substrate W and the upper surface of the guiding member 23 are included within the supply range of the first ionizer 21A. However, the supply range of cations may be set smaller if the pivot driver 272 or the movement driver 273 which displaces the first ionizer 21A is provided. For example, the cation supply range may be an elongated range having a longitudinal direction parallel to the longitudinal direction of the guiding member 23 (with reference to FIG. 17). The length of the cation supply range in the longitudinal direction is not less than the diameter of the substrate W. The pivot driver 272 or the movement driver 273 displaces the first ionizer 21A so that the cation supply range moves in the transverse direction thereof (in a right-and-left direction as seen in the plane of FIG. 17).

More specifically, the pivot driver 272 or the movement driver 273 displaces the first ionizer 21A between a first position in which the cation supply range is located on the guiding member 23 and a second position in which the cation supply range is located on the first main surface Wa of the substrate W. The second position is a position in which the supply range is located at the opposite end of the first main surface Wa of the substrate W from the first position. The first ionizer 21A in the first position supplies cations, whereby the guiding member 23 guides the cations to the second main surface Wb of the substrate W. This allows the second main surface Wb of the substrate W to be positively charged. The first main surface Wa of the substrate W is positively charged by supplying cations while the first ionizer 21A is moving from the first position to the second position.

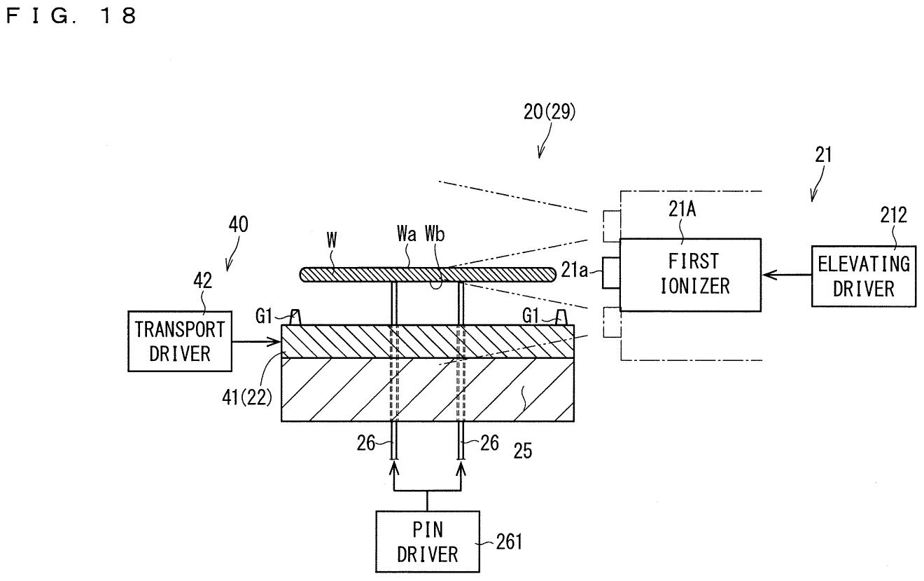

FIG. 18 is a view schematically showing a second example of the configuration of the electrostatic charging unit 20 according to the fifth embodiment. In the example of FIG. 18, the first ionizer 21A is provided in a position horizontally adjacent to the substrate W, with the substrate W supported by the multiple elevating pins 26. The outlet 21a of the first ionizer 21A may face a side surface of the substrate W in a horizontal direction. The first ionizer 21A is provided avoiding the transport path of the substrate W.

The vertical dimension of the outlet 21a of the first ionizer 21A may be greater than the thickness of the substrate W. The first ionizer 21A may cause the cations and the carrier gas to flow out of the outlet 21a. Some of the cations flowing out of the outlet 21a of the first ionizer 21A flow along the first main surface Wa and the second main surface Wb of the substrate W. Thus, the first main surface Wa and the second main surface Wb of the substrate W are positively charged.

As shown in FIG. 18, the electrostatic charger 21 may further include an elevating driver 212. The elevating driver 212 changes the relative positional relationship between the substrate W supported by the elevating pins 26 and the first ionizer 21A. In the example of FIG. 18, the elevating driver 212 moves the first ionizer 21A upwardly and downwardly. The elevating driver 212 moves the first ionizer 21A upwardly and downwardly between an upper surface position and a lower surface position which will be described below. The upper surface position is, for example, a position in which the center of the outlet 21a of the first ionizer 21A is above the first main surface Wa of the substrate W and in which more cations are supplied to the first main surface Wa of the substrate W. The lower surfacer position is, for example, a position in which the center of the outlet 21a of the first ionizer 21A is below the second main surface Wb of the substrate W and in which more cations are supplied to the second main surface Wb of the substrate W. In the example of FIG. 18, the first ionizer 21A which stops at each of the upper and lower surface positions is shown schematically in dash-dot lines. The elevating driver 212 includes, for example, a drive source such as a motor, and a power transmission part for transmitting the drive power of the drive source to the first ionizer 21A. The power transmission part includes, for example, a ball screw mechanism. The elevating driver 212 is controlled by the controller 90.

In Step S2, the controller 90 may cause the elevating driver 212 to move the first ionizer 21A from one of the upper and lower surface positions to the other thereof while operating the first ionizer 21A. Alternatively, the controller 90 may cause the elevating driver 212 to move the first ionizer 21A back and forth between the upper and lower surface positions. This allows the first main surface Wa and the second main surface Wb of the substrate W to be appropriately positively charged.

The fifth embodiment may be applied to the second ionizer 24A of the second embodiment. That is, the second ionizer 24A may supply ions to the first main surface Wa and the second main surface Wb of the substrate W to eliminate static from the first main surface Wa and the second main surface Wb of the substrate W.

### Sixth Embodiment

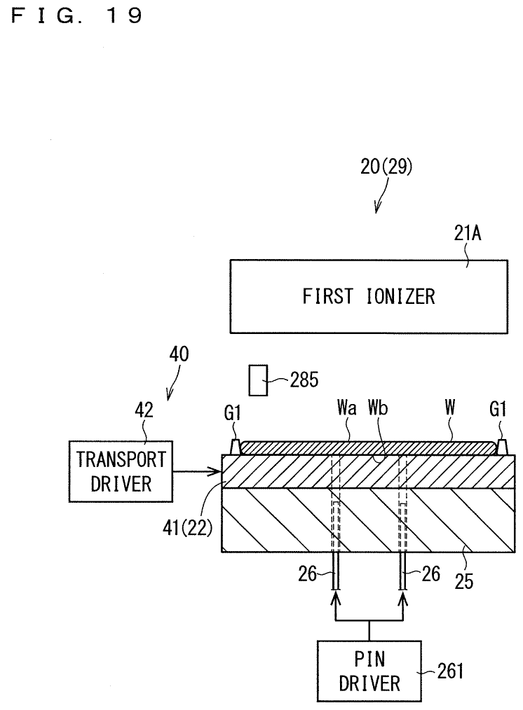

The substrate processing apparatus 100 according to a sixth embodiment differs in configuration of the electrostatic charging unit 20 from the substrate processing apparatus 100 according to the first embodiment. FIG. 19 is a view schematically showing a first example of the configuration of the electrostatic charging unit 20 according to the sixth embodiment. The electrostatic charging unit 20 of the sixth embodiment further includes an electrostatic charge sensor 285, as compared with the first embodiment. The electrostatic charge sensor 285 is, for example, a surface potential sensor. For example, the surface potential sensor has a sensing electrode, and measures the electric potential of a measurement target by detecting an induced potential generated on the sensing electrode in response to the electric potential of the measurement target. The electrostatic charge sensor 285 measures the electric potential of the first main surface Wa of the substrate W placed on the substrate receiving part 22 to output an electric signal indicating the measurement result to the controller 90. The electric potential measured by the electrostatic charge sensor 285 is also referred to hereinafter as a measured potential.

In the example of FIG. 19, the electrostatic charge sensor 285 is provided in a position facing a portion of the substrate W in a vertical direction. As an example, the electrostatic charge sensor 285 measures the electric potential of that portion (measurement region) of the first main surface Wa of the substrate W.

The electrostatic charging unit 20 may include a movement driver (not shown) for moving the electrostatic charge sensor 285. The movement driver may move the electrostatic charge sensor 285 between a measurement position and a standby position both to be described below. The measurement position is a position in which the electrostatic charge sensor 285 is vertically opposed to the first main surface Wa of the substrate W. The standby position is a position in which the electrostatic charge sensor 285 is not vertically opposed to the first main surface Wa of the substrate W and, for example, a position outside the substrate W in a radial direction. The standby position is also a position in which the electrostatic charge sensor 285 does not interfere with the transport path of the substrate W. The movement driver includes, for example, a drive source such as a motor, and a power transmission part for transmitting the drive power of the drive source to the electrostatic charge sensor 285. The power transmission part includes, for example, a ball screw mechanism. With the electrostatic charge sensor 285 moved to the standby position by the movement driver, the first ionizer 21A may supply cations to the first main surface Wa of the substrate W. This avoids the cations being blocked by the electrostatic charge sensor 285. On the other hand, the movement driver may move the electrostatic charge sensor 285 to the measurement position during the measurement of the electric potential of the substrate W.

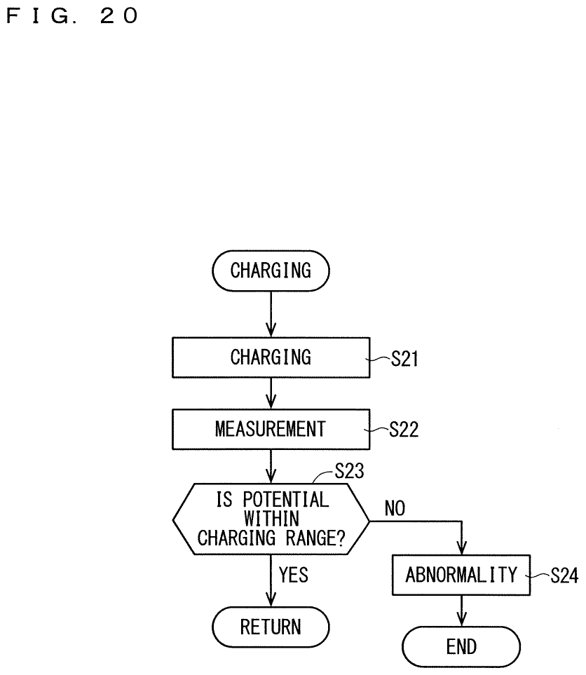

An example of the operation of the dry processing unit 121D according to the sixth embodiment is the same as that shown in FIG. 5 except a specific example of the operation in Step S2. FIG. 20 is a flow diagram showing a first example of the operation of the electrostatic charging unit 20 according to the sixth embodiment. The flow diagram of FIG. 20 corresponds to a specific example of the operation in Step S2. First, the controller 90 puts the first ionizer 21A into operation (Step S21). Thus, the first ionizer 21A causes cations to flow out of the outlet 21a, thereby supplying the cations to the first main surface Wa of the substrate W. In this case, it is assumed that the supply range of cations by means of the first ionizer 21A is wider than the first main surface Wa of the substrate W. The first ionizer 21A supplies cations to the first main surface Wa of the substrate W for a predetermined charging time period. In Step S21, the electrostatic charge sensor 285 may be located in the standby position.

Next, the electrostatic charge sensor 285 measures the electric potential of the first main surface Wa of the substrate W to output the measurement result to the controller 90 (Step S22). In Step S22, the electrostatic charge sensor 285 is located in the measurement position.

Next, the controller 90 judges whether the measured potential is within a predetermined charging range or not (Step S23). As a specific example, the controller 90 judges whether the measured potential is less than a predetermined charging reference value or not. The charging reference value is set in advance to a value (e.g., tens of volts) at which the substrate W is able to sufficiently repel metal ions in the gas bake process. When the measured potential is not less than the predetermined charging reference value, the controller 90 judges that the charging process is appropriately completed, and executes Step S3 and its subsequent processes.

On the other hand, when the measured potential is less than the predetermined charging reference value, the controller 90 performs an abnormality process (Step S24). As an example of the abnormality process, the controller 90 may suspend the processes of the substrate W or may provide notification of error information to a user by means of a notifying part not shown. The notifying part includes at least one of a display and a sound output part, for example. The display includes, for example, a liquid crystal display. The sound output part includes, for example, a speaker or a buzzer.

In the sixth embodiment, as described above, the electrostatic charge sensor 285 measures the electric potential of the first main surface Wa of the substrate W to output the measurement result to the controller 90. For this reason, prior to the gas bake process, the controller 90 recognizes that the substrate W is charged to the extent that metal contamination is appropriately reduced. This reduces the metal contamination of the substrate W more reliably in the gas bake process using the gas bake unit 30. Conversely, the dry processing unit 121D does not perform the gas bake process on the substrate W when the first main surface Wa of the substrate W is not sufficiently positively charged. Thus, the unnecessary gas bake process in the gas bake unit 30 is avoided. In addition, the user recognizes the abnormality by the notifying part.

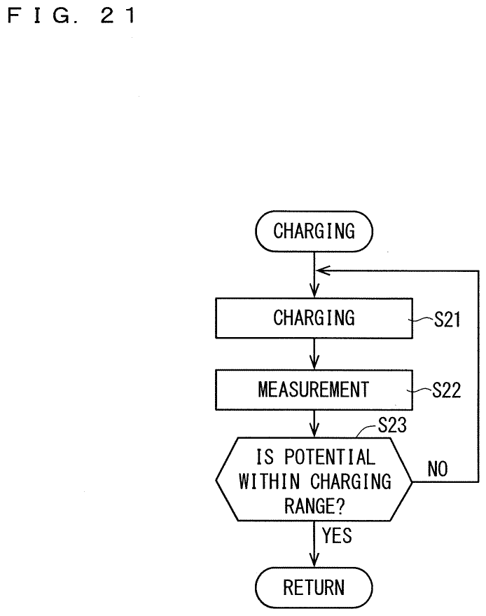

FIG. 21 is a flow diagram showing a second example of the operation of the electrostatic charging unit 20 according to the sixth embodiment. The flow diagram of FIG. 21 also corresponds to a specific example of the operation in Step S2. In the example of FIG. 21, Steps S21, S22, and S23 are also executed in this order. However, in the example of FIG. 21, when the measured potential is less than the predetermined charging reference value in Step S23, the controller 90 continues the operation of the first ionizer 21A in Step S21. In other words, when the first main surface Wa of the substrate W is still insufficiently charged, the electrostatic charging unit 20 continues to supply cations by means of the first ionizer 21A. This further increases the electric potential (the amount of charge) of the first main surface Wa of the substrate W.

On the other hand, when the measured potential is not less than the predetermined charging reference value in Step S23, the controller 90 stops the first ionizer 21A and executes Step S3 and its subsequent processes.

In the example of FIG. 21, as described above, the charging process is continued when the charging is insufficient. This allows the electrostatic charging unit 20 to charge the first main surface Wa of the substrate W more reliably with a sufficient amount of charge.

It can be assumed in some cases that the first main surface Wa of the substrate W is not sufficiently charged due to an abnormality or the like after multiple times of execution of Step S21. For this reason, the controller 90 may measure the number of times that the measured potential is judged to be less than the predetermined charging reference value in Step S23, and perform the abnormality process (Step S24) when the number of times exceeds a predetermined reference value of the number of times (e.g., three times).

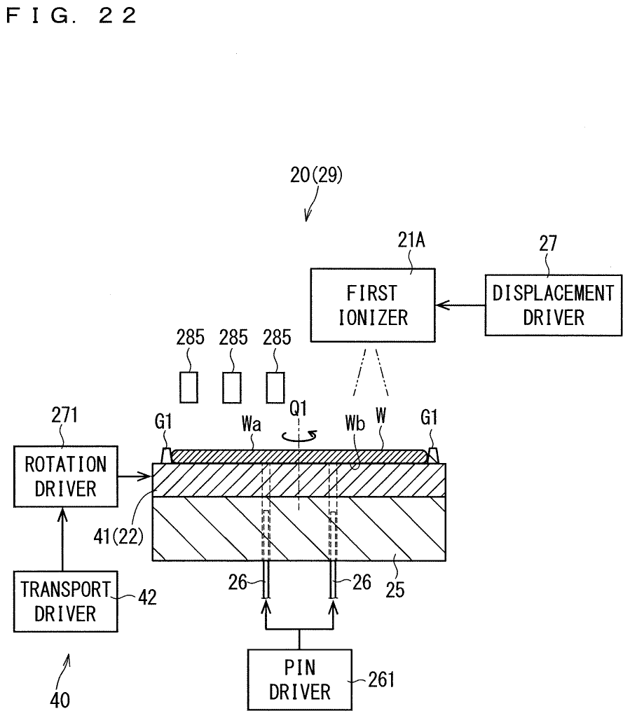

FIG. 22 is a view schematically showing a second example of the configuration of the electrostatic charging unit 20 according to the sixth embodiment. In the example of FIG. 22, the electrostatic charging unit 20 includes multiple electrostatic charge sensors 285. The multiple electrostatic charge sensors 285 measure the electric potentials at different measurement positions of the first main surface Wa of the substrate W. As an example, the multiple electrostatic charge sensors 285 may measure the electric potentials at different radial positions of the first main surface Wa of the substrate W.

An example of the operation of the electrostatic charging unit 20 according to the second example of the sixth embodiment is the same as that of FIG. 20 or FIG. 21. However, in Step S22, all of the multiple electrostatic charge sensors 285 measure the electric potentials. This allows the controller 90 to obtain the measured potentials at the different measurement positions.

In Step S23, the controller 90 may judge whether the measured potential is less than the charging reference value or not for each of the multiple electrostatic charge sensors 285. When all of the measured potentials are judged to be not less than the charging reference value, the controller 90 judges that the substrate W is sufficiently charged, and executes Step S3 and its subsequent processes.

On the other hand, when at least one of the measured potentials is less than the charging reference value, the controller 90 may perform the abnormality process (Step S24) or continue the charging process (Step S21).

In the example of FIG. 22, the electrostatic charging unit 20 includes the displacement driver 27. In this case, it is assumed that the supply range of cations by means of the first ionizer 21A is smaller in size than the first main surface Wa of the substrate W. For example, the pivot driver 272 or the movement driver 273 is applicable as the displacement driver 27. In this case, while operating the first ionizer 21A, the controller 90 causes the displacement driver 27 to displace the first ionizer 21A, thereby supplying the cations to the entire first main surface Wa of the substrate W, in Step S21 that is an initial step.

Then, when a measured potential is less than the charging reference value in Step S23, the controller 90 executes Step S21 again. In Step S21 executed again, the controller 90 may control the displacement driver 27 so as to supply cations only to the vicinity of the measurement region of an electrostatic charge sensor 285 which has measured the potential less than the charging reference value. In other words, the first ionizer 21A causes cations to flow toward the region where the amount of charge is insufficient, and does not cause cations to flow toward at least some of the regions where the amount of charge is sufficient. This reduces the unnecessary operation of the first ionizer 21A while increasing the amount of charge in the region of the first main surface Wa of the substrate W where the amount of charge is insufficient. Thus, the power consumption of the first ionizer 21A is reduced. In other words, the electrostatic charging unit 20 is capable of positively charging the first main surface Wa of the substrate W more reliably with low power consumption.

In the example of FIG. 22, the electrostatic charging unit 20 further includes the rotation driver 271. The first ionizer 21A may perform spot irradiation of cations on the first main surface Wa of the substrate W. In this case, the displacement driver 27 may displace the first ionizer 21A so that a spot-like cation supply range moves radially along the first main surface Wa of the substrate W. In this case, while causing the rotation driver 271 to rotate the substrate W, the controller 90 may cause the displacement driver 27 to move the supply range in the radial direction of the substrate W in Step S21 that is an initial step. Thus, the cations are supplied to the entire first main surface Wa of the substrate W in Step S21.

In Step S22, the multiple electrostatic charge sensors 285 measure the electric potentials at the different radial positions of the first main surface Wa of the substrate W. Then, in Step S23, when at least one of the measured potentials is less than the charging reference value in Step S23, the controller 90 may control the displacement driver 27 in Step S21 so that the first ionizer 21A causes cations to flow out toward the same radial position as the measurement region of the at least one electrostatic charge sensor 285 which has measured the potential less than the charging reference value. Then, the rotation driver 271 rotates the substrate W in this state. Thus, the first ionizer 21A is able to supply the cations to an annular region including the position in which the amount of charge is insufficient on the first main surface Wa of the substrate W. This increases the amount of charge in the annular region in which the amount of charge is insufficient on the first main surface Wa of the substrate W. Conversely, the first ionizer 21A does not cause the cations to flow out toward an annular region including the position in which the measured potential not less than the charging reference value is measured, thereby reducing the power consumption of the first ionizer 21A.

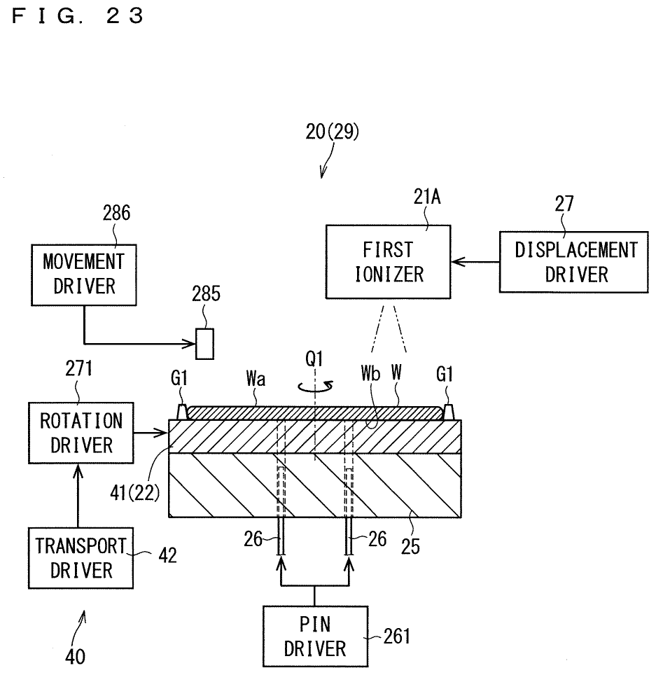

FIG. 23 is a view schematically showing a third example of the configuration of the electrostatic charging unit 20 according to the sixth embodiment. In the example of FIG. 23, the electrostatic charging unit 20 further includes a movement driver 286. The movement driver 286 changes the relative positional relationship between the substrate W placed on the substrate receiving part 22 and the electrostatic charge sensor 285 to move the measurement position on the first main surface Wa of the substrate W. As an example, the movement driver 286 may move the electrostatic charge sensor 285 one-dimensionally in a radial direction of the substrate W or two-dimensionally in a horizontal plane. The movement driver 286 includes a drive source such as a motor, and a power transmission part for transmitting the drive power of the drive source to the electrostatic charge sensor 285. The power transmission part includes, for example, a ball screw mechanism.

An example of the operation of the electrostatic charging unit 20 according to the third example of the sixth embodiment is the same as that of FIG. 20 or FIG. 21. However, in Step S22, the controller 90 controls the movement driver 286 so that the measurement position moves on the first main surface Wa of the substrate W. The electrostatic charge sensor 285 measures the electric potential at each measurement position to output the measurement result to the controller 90. This allows the controller 90 to obtain a more detailed potential distribution of the first main surface Wa of the substrate W. Thus, the controller 90 is able to grasp a region in which the amount of charge is insufficient on the first main surface Wa of the substrate W with higher spatial resolution. Other operations are the same as those of the electrostatic charging unit 20 of the second example of the sixth embodiment.

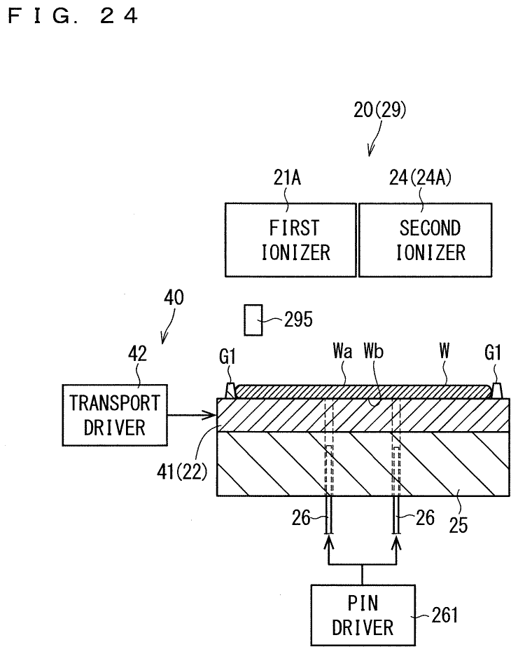

FIG. 24 is a view schematically showing a fourth example of the configuration of the electrostatic charging unit 20 according to the sixth embodiment. In the example of FIG. 24, the electrostatic charging unit 20 includes the first ionizer 21A and the second ionizer 24A. The second ionizer 24A eliminates static from the first main surface Wa of the substrate W.

An example of the operation of the dry processing unit 121D according to the fourth example of the sixth embodiment is the same as that shown in FIG. 10 except a specific example of the operation in Step S60.

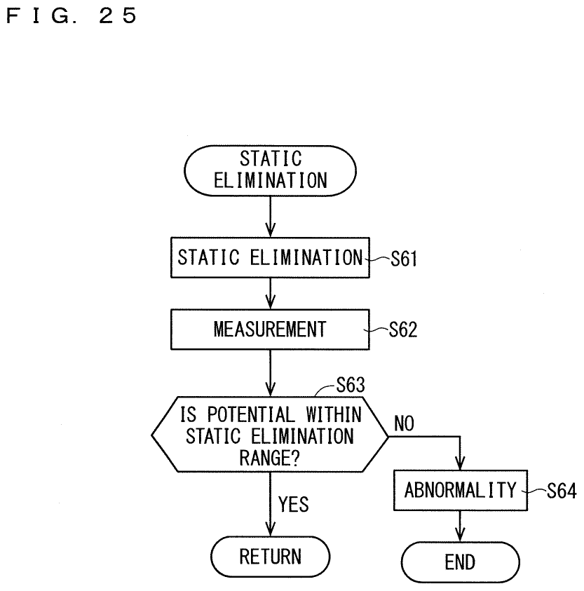

FIG. 25 is a flow diagram showing a first example of the operation of the electrostatic charging unit 20 according to the fourth example of the sixth embodiment. FIG. 25 corresponds to a specific example of the operation in Step S60 (Cooling and static elimination step) of FIG. 10. In FIG. 25, the operation relating to the cooling of the substrate W is dispensed with, and an example of the operation relating to the static elimination is shown.

First, the controller 90 puts the second ionizer 24A into operation (Step S61). The second ionizer 24A supplies ions (including negative particles) to the entire first main surface Wa of the substrate W. As a result, the amount of charge (the absolute value of the electric potential) of the substrate W decreases over time. The second ionizer 24A supplies ions to the first main surface Wa of the substrate W over a predetermined static elimination time period.

Next, the electrostatic charge sensor 285 measures the electric potential of the first main surface Wa of the substrate W to output the measurement result to the controller 90 (Step S62).

Next, the controller 90 judges whether the measured potential is within a predetermined static elimination range or not (Step S63). The static elimination range is set in advance, for example, to a range (e.g., not less than −1 V and less than 1 V) in which the adhesion of particles to the substrate W due to charging hardly occurs. When the measured potential is outside the static elimination range, the controller 90 performs an abnormality process (Step S64). On the other hand, when the measured potential is within the static elimination range, the controller 90 judges that the static elimination process is appropriately completed. Then, if the substrate W is sufficiently cooled, the controller 90 performs the process in Step S7.

As described above, the electrostatic charge sensor 285 measures the electric potential of the first main surface Wa of the substrate W in Step S62. This allows the controller 90 to recognize that static is eliminated from the substrate W, for example, to the extent of suppressing the adhesion of particles, before the second transport part 122 transports the substrate W outwardly. Conversely, when static is not sufficiently eliminated from the substrate W, a user recognizes an abnormality by means of the notifying part.

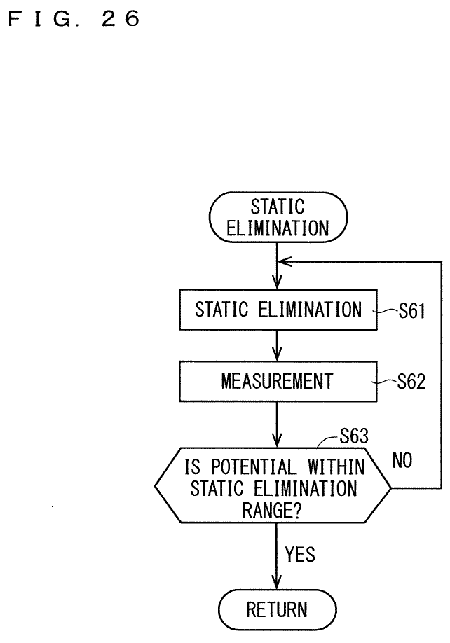

FIG. 26 is a flow diagram showing a second example of the operation of the electrostatic charging unit 20 according to the fourth example of the sixth embodiment. The flow diagram of FIG. 26 also corresponds to a specific example of the operation in Step S60. In the example of FIG. 26, Steps S61, S62, and S63 are also executed in this order. However, in the example of FIG. 26, when the measured potential is outside the static elimination range in Step S63, the controller 90 continues the operation of the second ionizer 24A in Step S61. In other words, when static is still insufficiently eliminated from the first main surface Wa of the substrate W, the electrostatic charging unit 20 continues to supply charged particles by means of the second ionizer 24A. This further reduces the amount of charge of the first main surface Wa of the substrate W.

On the other hand, when the measured potential is within the static elimination range in Step S63, the controller 90 stops the second ionizer 24A and executes Step S7 because static is sufficiently eliminated from the first main surface Wa of the substrate W.

In the example of FIG. 26, as described above, the static elimination process is continued when the static elimination is insufficient. This allows the electrostatic charging unit 20 to eliminate static from the first main surface Wa of the substrate W more reliably.

It can be assumed in some cases that static is not sufficiently eliminated from the first main surface Wa of the substrate W due to an abnormality or the like after multiple times of execution of Step S61. For this reason, the controller 90 may measure the number of times that the measured potential is judged to be outside the static elimination range in Step S63, and perform the abnormality process (Step S64) when the number of times exceeds a predetermined reference value of the number of times (e.g., three times).

In addition, the electrostatic charging unit 20 may include multiple electrostatic charge sensors 285. Alternatively, the electrostatic charging unit 20 may include the movement driver 286 for moving the electrostatic charge sensor 285. This allows the controller 90 to obtain measured potentials at multiple measurement positions on the first main surface Wa of the substrate W.

The controller 90 may continue operating the second ionizer 24A until all of the measured potentials are within the predetermined static elimination range. When the second ionizer 24A causes both cations and negative particles to flow out, charged particles in accordance with the electric potential of a region in which static elimination is insufficient are attracted, so that the electric potential of that region is appropriately reduced.

### Seventh Embodiment

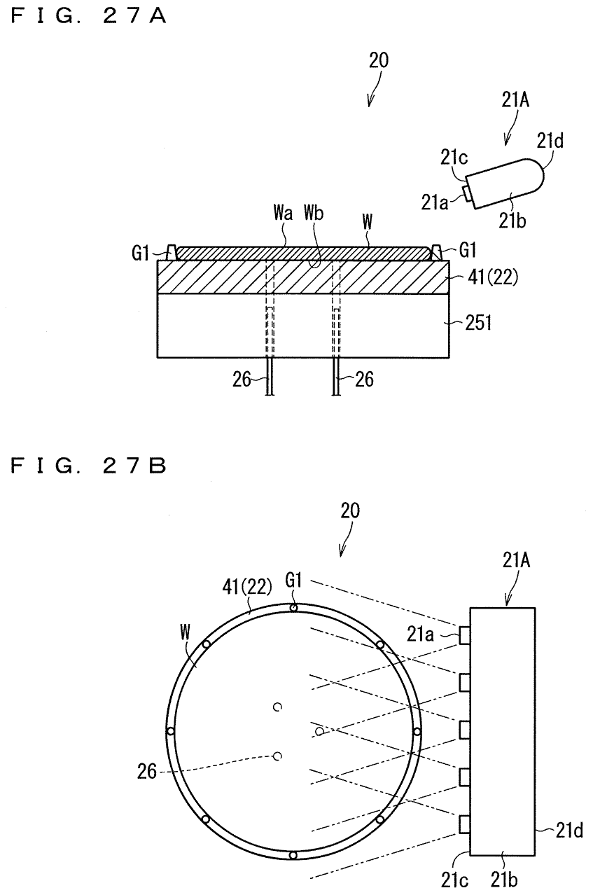

FIGS. 27A and 27B are views schematically showing a first example of the electrostatic charging unit 20 according to a seventh embodiment. FIG. 27A is a side view of the electrostatic charging unit 20, and FIG. 27B is a plan view of the electrostatic charging unit 20. In the seventh embodiment, the position of the first ionizer 21A will be described. In the example of FIGS. 27A and 27B, the first ionizer 21A includes multiple outlets 21a. All of the multiple outlets 21a are located off the center of the substrate W as seen in plan view. As a more specific example, all of the multiple outlets 21a are provided outside the substrate W as seen in plan view. In other words, the multiple outlets 21a of the first ionizer 21A are provided avoiding a region vertically opposed to the substrate W placed on the substrate receiving part 22.

The first ionizer 21A further includes an enclosure 21b. In the example of FIGS. 27A and 27B, the enclosure 21b is also provided avoiding the region vertically opposed to the substrate W. The enclosure 21b of the first ionizer 21A has an elongated shape as seen in plan view. The longitudinal direction of the enclosure 21b may be, for example, parallel to a tangent line of the periphery of the substrate W which is in a position closest to the first ionizer 21A.

The enclosure 21b is provided in an oblique attitude as seen in the longitudinal direction (as seen in side view). Specifically, the enclosure 21b is provided in an oblique attitude so that a first end portion 21c of the enclosure 21b which is closer to the substrate W is below a second end portion 21d of the enclosure 21b which is farther from the substrate W as seen in side view.

The outlets 21a of the first ionizer 21A are formed on the first end portion 21c. The outlets 21a of the first ionizer 21A cause cations to flow out in an obliquely downward direction. The cations flow out of the outlets 21a toward the first main surface Wa of the substrate W.

In the example of FIGS. 27A and 27B, the multiple outlets 21a are arranged in spaced apart relation in the longitudinal direction of the first ionizer 21A. In FIG. 27B, the range of supply of cations from each of the outlets 21a of the first ionizer 21A is shown schematically in dash-double-dot lines. As shown in FIG. 27B, the cations reach the first main surface Wa of the substrate W while spreading out as going away from the outlets 21a. In the example of FIGS. 27A and 27B, the multiple outlets 21a are arranged at intervals which allow the cations to be supplied to the entire first main surface Wa of the substrate W.

Since the cations flow in a spreading manner from the outlets 21a, a sufficiently large distance from each of the outlets 21a to the first main surface Wa of the substrate W is required for the supply of the cations to the first main surface Wa of the substrate W in a sufficient supply range. In the seventh embodiment, the outlets 21a of the first ionizer 21A are located outside the substrate W, and the cations flow out obliquely downwardly from the outlets 21a toward the substrate W. This ensures the large distance between the outlets 21a and the first main surface Wa of the substrate W while suppressing the increase in vertical dimension of the electrostatic charging unit 20. Thus, the cations in a sufficiently spreading state reach the first main surface Wa of the substrate W. The first ionizer 21A is hence able to supply the cations to the entire first main surface Wa of the substrate W more reliably.

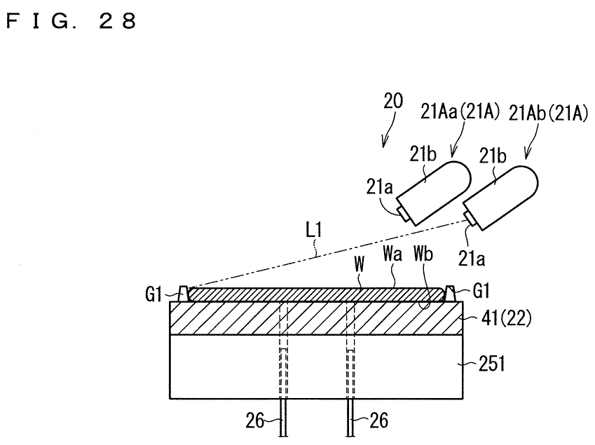

The multiple outlets 21a may be arranged two-dimensionally, although arranged one-dimensionally in the longitudinal direction of the enclosure 21b in the example of FIGS. 27A and 27B. FIG. 28 is a view schematically showing a second example of the configuration of the electrostatic charging unit 20 according to the seventh embodiment. In the second example of the seventh embodiment, multiple first ionizers 21A are provided. In the example of FIG. 28, two first ionizers 21Aa and 21Ab are provided as the multiple first ionizers 21A. The first ionizers 21Aa and 21Ab are adjacent to each other in a horizontal array direction orthogonal to the longitudinal direction of the enclosures 21b. The first ionizers 21Aa and 21Ab are provided in positions which are off the center of the substrate W placed on the substrate receiving part 22 toward one side of the array direction as seen in plan view. In the example of FIG. 28, the first ionizer 21Aa is provided in a position vertically opposed to the substrate W, and the first ionizer 21Ab is provided in a position not vertically opposed to the substrate W.

The outlets 21a of the first ionizer 21Aa and the outlets 21a of the first ionizer 21Ab cause cations to flow out obliquely downwardly. The first ionizer 21Aa is provided so that the cation supply range thereof includes a position of the first main surface Wa of the substrate W which is farthest from the first ionizer 21Aa. The first ionizer 21Ab is provided so that the entire cation supply ranges of the first ionizers 21Aa and 21Ab include the first main surface Wa of the substrate W.

The first ionizer 21Ab can be provided so that all imaginary lines L1 connecting the centers of the outlets 21a of the first ionizer 21Ab and each point on the periphery of the first main surface Wa of the substrate W do not collide with the first ionizer 21Aa. In FIG. 28, the imaginary line L1 closest to the first ionizer 21Aa is shown. This makes the cations from the first ionizer 21Ab less liable to collide with the first ionizer 21Aa, so that the cations are supplied to the first main surface Wa of the substrate W more efficiently.

### Eighth Embodiment

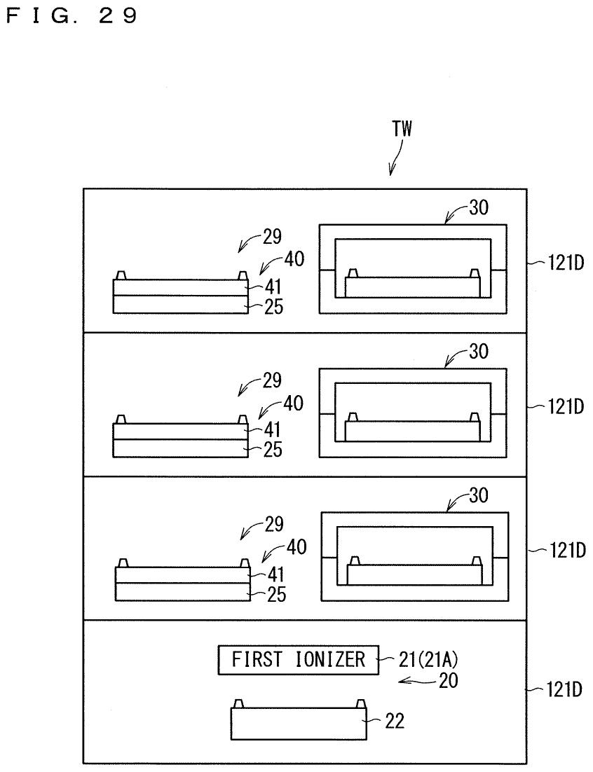

In the first to seventh embodiments, the electrostatic charging unit 20 (specifically, the electrostatic charger 21) is provided in the cooling unit 29 or the gas bake unit 30. However, the electrostatic charging unit 20 is not limited to this. FIG. 29 is a view schematically showing an example of the configuration of a tower TW of the substrate processing apparatus 100 according to an eighth embodiment. In the example of FIG. 29, the tower TW includes four dry processing units 121D stacked together in a vertical direction. However, the number of dry processing units 121D constituting the tower TW is not limited to four.

As shown in FIG. 29, one of the multiple dry processing units 121D may include the electrostatic charging unit 20 without including the cooling unit 29 and the gas bake unit 30. In the example of FIG. 29, the lowermost dry processing unit 121D consists solely of the electrostatic charging unit 20. The electrostatic charger 21 of the electrostatic charging unit 20 includes the first ionizer 21A. In the example of FIG. 29, the remaining dry processing units 121D in the tower TW do not include the electrostatic charging unit 20.

In such a structure, the second transport part 122 transports the substrate W from the wet processing unit 121W to the electrostatic charging unit 20. Thus, the substrate W is placed on the substrate receiving part 22 of the electrostatic charging unit 20. The first ionizer 21A of the electrostatic charging unit 20 supplies cations to the first main surface Wa of the substrate W to positively charge the first main surface Wa of the substrate W. Then, the second transport part 122 transports the substrate W from the electrostatic charging unit 20 to the cooling unit 29 (the transport unit 40). During this transport, it is necessary that the charged state of the substrate W is maintained. For this reason, at least a contact portion of a hand of the second transport part 122 which contacts the substrate W and at least contact portions of the elevating pins 26 which contact the substrate W are made of an insulative material. For example, ceramics or organic resin is applied as the insulative material. This allows the second transport part 122 to transport the substrate W from the electrostatic charging unit 20 to the cooling unit 29 (the transport unit 40) while maintaining the charged state of the substrate W. Then, the transport unit 40 transports the substrate W to the gas bake unit 30, and the gas bake unit 30 performs the gas bake process on the substrate W. This also allows the gas bake unit 30 to perform the gas bake process while suppressing metal contamination.

The number of electrostatic charging units 20 in each of the towers TW may be not greater than half of the number of dry processing units 121D constituting each of the towers TW. For example, if a tower TW consists of four dry processing units 121D, one electrostatic charging unit 20 may be provided in the tower TW (with reference to FIG. 29). In this case, the electrostatic charging unit 20 is provided in corresponding relation to the multiple gas bake units 30. There is no need to provide the electrostatic charging unit 20 for each of the gas bake units 30. This reduces the manufacturing costs of the substrate processing apparatus 100.

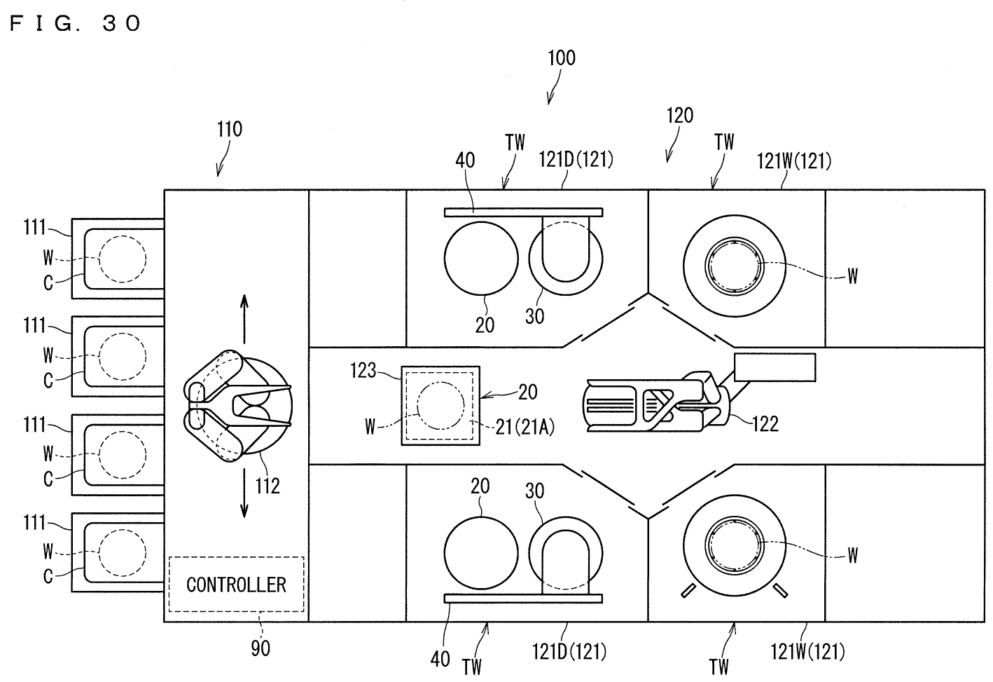

FIG. 30 is a view schematically showing another example of the configuration of the substrate processing apparatus 100 according to the eighth embodiment. As shown in FIG. 30, the electrostatic charging unit 20 may be provided in the relay part 123. The relay part 123 is provided between the first transport part 112 and the second transport part 122, and relays the substrate W. The relay part 123 is provided with a substrate receiving part (not shown, e.g., a mounting table) on which the substrate W is placed in a horizontal attitude. The electrostatic charger 21 of the electrostatic charging unit 20 includes the first ionizer 21A. The first ionizer 21A supplies cations to the first main surface Wa of the substrate W placed on the substrate receiving part to positively charge the first main surface Wa of the substrate W.

### Ninth Embodiment

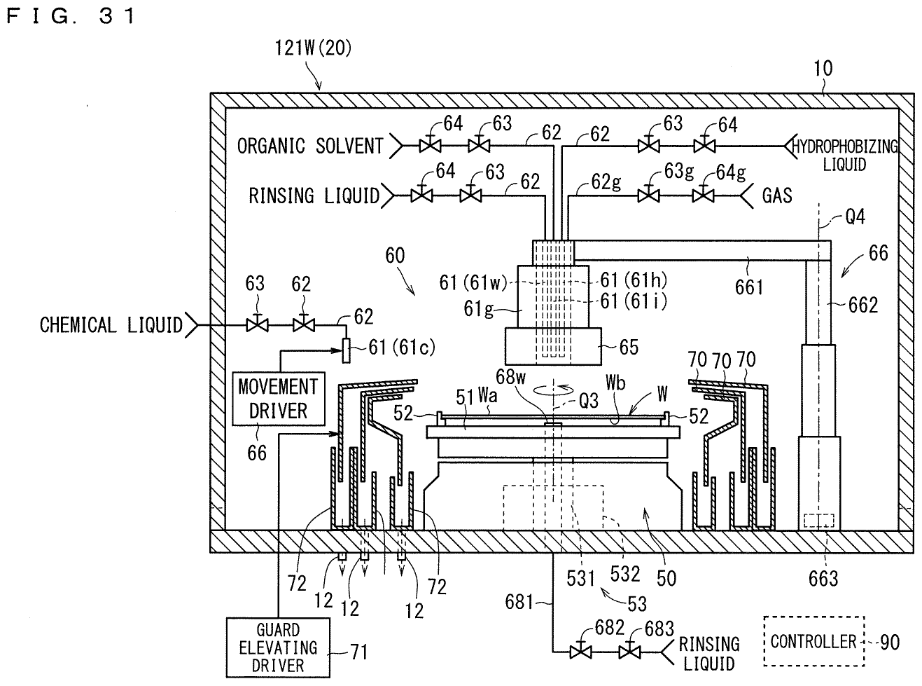

FIG. 31 is a view schematically showing an example of the configuration of the electrostatic charging unit 20 according to a ninth embodiment. In the ninth embodiment, the electrostatic charging unit 20 functions also as the wet processing unit 121W. It is not necessary that all wet processing units 121W belonging to the substrate processing apparatus 100 have the configuration illustrated in FIG. 31. It is sufficient that at least one of the wet processing units 121W in the substrate processing apparatus 100 has the configuration illustrated in FIG. 31.

In the ninth embodiment, the substrate W processed by the wet processing unit 121W is transported to the dry processing unit 121D by the second transport part 122. During this transport, it is necessary that the charged state of the substrate W is maintained. For this reason, at least the contact portion of the hand of the second transport part 122 which contacts the substrate W is made of an insulative material. For example, ceramics or organic resin is applied as the insulative material. This allows the second transport part 122 to transport the substrate W from the wet processing unit 121W to the dry processing unit 121D while maintaining the charged state of the substrate W. In this case, the dry processing unit 121D includes the cooling unit 29 and the gas bake unit 30. In the ninth embodiment, the dry processing unit 121D need not include the electrostatic charging unit 20 because the wet processing unit 121W functions also as the electrostatic charging unit 20.

As shown in FIG. 31, the wet processing unit 121W includes a substrate holder 50 for holding the substrate W, a first dispenser 60 for dispensing a processing liquid toward the first main surface Wa of the substrate W, and a second dispenser 67 for dispensing a rinsing liquid toward the second main surface Wb of the substrate W.

In the example of FIG. 31, the wet processing unit 121W is provided with a chamber 10. The chamber 10 has a box-like shape. The interior space of the chamber 10 corresponds to a processing space for processing the substrate W therein. The chamber 10 is provided with an openable/closable transport opening (not shown). The second transport part 122 transports an unprocessed substrate W through the transport opening into the chamber 10, and transports a processed substrate W through the transport opening out of the chamber 10.

The substrate holder 50 is provided in the chamber 10, and rotates the substrate W about a rotational axis Q3 while holding the substrate W in a horizontal attitude. The rotational axis Q3 is an axis passing through the center of the substrate W held by the substrate holder 50 and extending in a vertical direction. Such a substrate holder 50 is referred to also as a spin chuck.

The substrate holder 50 holds the substrate W by a chucking method such as a mechanical chuck, a vacuum chuck, an electrostatic chuck, and a Bernoulli chuck. In the example of FIG. 31, the substrate holder 50 holds the substrate W by a mechanical chuck method. For example, the substrate holder 50 includes a spin base 51, chuck pins 52, and a rotation driver 53. The spin base 51 has a planar shape (e.g., a disk-like shape), and is provided in an attitude in which the thickness direction thereof extends in a vertical direction. The multiple chuck pins 52 are provided on an upper surface of the spin base 51. The multiple chuck pins 52 are equally spaced in a circumferential direction about the rotational axis Q3. The multiple chuck pins 52 are displaceable between a holding position and a release position which will be described below. The holding position refers to a position in which the chuck pins 52 abut against the periphery of the substrate W. The multiple chuck pins 52 stop in their respective holding positions to thereby hold the substrate W. In FIG. 31, the chuck pins 52 are shown stopped in the holding positions. The release position is a position in which each of the chuck pins 52 is separate from the substrate W. The multiple chuck pins 52 stop in their release positions, whereby the holding of the substrate W by the multiple chuck pins 52 is released. The substrate holder 50 further includes a pin driver (not shown) for displacing the chuck pins 52. The pin driver includes, for example, a drive source such as a motor and an air cylinder, and is controlled by the controller 90.

The rotation driver 53 includes a shaft 531 and a motor 532. The shaft 531 has an upper end connected to a lower surface of the spin base 51, and extends from the lower surface of the spin base 51 along the rotational axis Q3. The motor 532 is controlled by the controller 90, and rotates the shaft 531 about the rotational axis Q3. Thus, the spin base 51, the chuck pins 52, and the substrate W rotate integrally about the rotational axis Q3.

Contact portions (e.g., the chuck pins 52) of the substrate holder 50 which contact the substrate W are made of an insulative material. For example, ceramics or organic resin is applied as the insulative material. This allows the substrate holder 50 to hold the substrate W while maintaining the charged state of the substrate W.

The first dispenser 60 dispenses various processing liquids in order toward the first main surface Wa (e.g., the upper surface) of the substrate W held by the substrate holder 50. When the first dispenser 60 dispenses a processing liquid toward the first main surface Wa of the substrate W which is rotating, the processing liquid which has adhered to the first main surface Wa of the substrate W flows radially outwardly due to centrifugal force and flies outwardly from the periphery of the substrate W. At this time, the processing liquid acts on the first main surface Wa of the substrate W, whereby a process in accordance with the type of processing liquid is performed on the substrate W.

The various processing liquids include a chemical liquid for processing the substrate W, and a rinsing liquid for washing the chemical liquid away from the first main surface Wa of the substrate W. Examples of the chemical liquid include liquids for cleaning, etching, and hydrophobizing the substrate W. Examples of the cleaning or etching liquid include: dilute hydrofluoric acid; a mixture of aqueous ammonia, a hydrogen peroxide solution, and deionized water (SC-1 (standard cleaning 1; NH₄OH—H₂O₂—H₂O)); a mixture of hydrochloric acid, a hydrogen peroxide solution, and deionized water (SC-2 (standard cleaning 2; HCl—H₂O₂—H₂O)); a mixture of sulfuric acid and a hydrogen peroxide solution (SPM); and phosphoric acid. The hydrophobizing liquid is, for example, a silylation liquid containing a silylation agent (referred to also as a silane coupling agent) in liquid form. Examples of the rinsing liquid include deionized water and an organic solvent (e.g., isopropyl alcohol).

The first dispenser 60 dispenses various processing liquids in order toward the substrate W to thereby perform various processes on the substrate W. A specific example of the processes will be described below.

The second dispenser 67 dispenses a rinsing liquid toward the second main surface Wb (e.g., the lower surface) of the substrate W held by the substrate holder 50. An example of the rinsing liquid includes deionized water. When the second dispenser 67 dispenses the rinsing liquid toward the second main surface Wb of the substrate W which is rotating, the rinsing liquid which has adhered to the second main surface Wb of the substrate W flows radially outwardly due to centrifugal force and flies outwardly from the periphery of the substrate W. In this case, a dielectric film (e.g., SiO₂ film) is formed on the second main surface Wb of the substrate W. The rinsing liquid acts on the second main surface Wb of the substrate W, whereby the second main surface Wb of the substrate W is negatively charged, and the first main surface Wa of the substrate W is positively charged by induction charging.

As shown in FIG. 31, the first dispenser 60 includes at least one nozzle 61. The nozzle 61 dispenses a processing liquid toward the first main surface Wa of the substrate W held by the substrate holder 50. In the example of FIG. 31, the nozzle 61 is provided above the substrate W held by the substrate holder 50. The nozzle 61 is, for example, a straight nozzle which dispenses the processing liquid in the form of a continuous flow. The nozzle 61 extends, for example, in a vertical direction.

In the example of FIG. 31, nozzles 61c, 61w, 61i, and 61h are illustrated as the nozzle 61. The nozzle 61c dispenses a chemical liquid, and the nozzle 61w dispenses deionized water. The nozzle 61i dispenses an organic solvent, and the nozzle 61h dispenses a hydrophobizing liquid.

In the example of FIG. 31, the nozzles 61w, 61i, and 61h are adjacent to each other in a horizontal direction, and are fixed to each other. In the example of FIG. 31, the nozzles 61w, 61i, and 61h are provided inside an opposed member 65. The opposed member 65 has, for example, a cylindrical shape. The opposed member 65 has a hollow shape, and a lower end of the hollow portion is open at a lower surface of the opposed member 65. The nozzles 61w, 61i, and 61h are provided in the hollow portion of the opposed member 65, and the processing liquid dispensed from each of the nozzles 61w, 61i, and 61h flows out of the lower end opening of the opposed member 65. In the example of FIG. 31, the opposed member 65 is provided in a position vertically opposed to a central portion of the substrate W held by the substrate holder 50.

Each of the nozzles 61 is connected to a downstream end of a supply pipe 62 having an upstream end connected to a processing liquid source for supplying a corresponding processing liquid. A supply valve 63 and a flow regulating valve 64 are interposed in the supply pipe 62. The supply valve 63 switches between the opening and closing of the supply pipe 62. The flow regulating valve 64 is, for example, a massflow controller, and regulates the flow rate of the processing liquid flowing through the supply pipe 62. The supply valve 63 and the flow regulating valve 64 are controlled by the controller 90.

Although the single nozzle 61c is provided in the example of FIG. 31, multiple nozzles 61c may be provided. For example, a nozzle 61c for dilute hydrofluoric acid and a nozzle 61c for the SC-1 solution may be provided.

In the example of FIG. 31, the opposed member 65 is configured to be able to dispense gas toward the first main surface Wa of the substrate W held by the substrate holder 50. In the example of FIG. 31, the hollow space of the opposed member 65 other than the nozzle 61 functions as a gas flow passage 61g. The lower end opening of the lower surface of the opposed member 65 corresponds to an orifice of the gas flow passage 61g. In the example of FIG. 31, the opposed member 65 has an upper portion connected to a downstream end of a supply pipe 62g. In other words, the downstream end of the supply pipe 62g is connected to the gas flow passage 61g. The supply pipe 62g has an upstream end connected to a gas source. The gas source includes a reservoir (not shown) for storing an inert gas therein, and supplies the inert gas to the upstream end of the supply pipe 62g. The inert gas is, for example, nitrogen gas. The supply pipe 62g is provided with a supply valve 63g and a flow regulating valve 64g. The supply valve 63g switches between the opening and closing of the supply pipe 62g. The flow regulating valve 64g regulates the flow rate of the inert gas flowing through the supply pipe 62g. The supply valve 63g and the flow regulating valve 64g are controlled by the controller 90.

In the example of FIG. 31, the wet processing unit 121W is provided with movement drivers 66. In the example of FIG. 31, a movement driver 66 for the nozzle 61c and a movement driver 66 for the opposed member 65 are provided. The movement driver 66 for the nozzle 61c moves the nozzle 61c, and the movement driver 66 for the opposed member 65 moves a dispensing head including the nozzle 61w, the nozzle 61i, the nozzle 61h, and the opposed member 65 integrally. Each of the movement drivers 66 moves the nozzle 61c or the dispensing head between a processing position and a standby position both to be described below. The processing position is a position in which the nozzle 61 dispenses a processing liquid toward the first main surface Wa of the substrate W and, for example, a position vertically opposed to a central portion of the first main surface Wa of the substrate W. In the example of FIG. 31, the dispensing head stopped in the processing position is shown. The standby position is a position in which the nozzle 61 does not dispense the processing liquid toward the first main surface Wa of the substrate W and, for example, a position radially outside the substrate holder 50. In the example of FIG. 31, the nozzle 61c stopped in the standby position is shown.

A specific example of the configuration of the movement driver 66 is shown in FIG. 31. In the example of FIG. 31, the movement driver 66 includes an arm 661, a support column 662, and a drive source 663. The support column 662 is provided radially outside a guard 70 to be described later, and extends in a vertical direction. The arm 661 extends in a horizontal direction, and has a forward end connected to the dispensing head and a base end connected to the support column 662. The drive source 663 is controlled by the controller 90, and rotates the support column 662 in forward and reverse directions within a predetermined angular range about a central axis Q4 of the support column 662. The drive source 663 includes, for example, a motor. When the support column 662 rotates in forward and reverse directions within the predetermined angular range about the central axis Q4, the dispensing head moves back and forth in a circumferential direction about the central axis Q4. The support column 662 is installed so that the processing position and the standby position are located on the movement path of the dispensing head. The movement driver 66 is not necessarily limited to the form shown in FIG. 31, but may include a linear motion mechanism such as a linear motor.

The second dispenser 67 includes a nozzle 68w. The nozzle 68w dispenses the rinsing liquid toward the second main surface Wb of the substrate W held by the substrate holder 50. In the example of FIG. 31, the nozzle 68w is provided below the substrate W held by the substrate holder 50. The nozzle 68w is, for example, a straight nozzle which dispenses the processing liquid in the form of a continuous flow. The nozzle 68w extends, for example, in a vertical direction.

The nozzle 68w has an upper end (orifice) vertically facing a central portion of the second main surface Wb of the substrate W. The nozzle 68w has a lower end connected to a downstream end of a supply pipe 681. In the example of FIG. 31, a through hole is formed in a central portion of the spin base 51, and the shaft 531 is a hollow shaft. At least parts of the nozzle 68w and the supply pipe 681 extend in a vertical direction inside the spin base 51 and the shaft 531. The supply pipe 681 has an upstream end connected to a rinsing liquid source. A supply valve 682 and a flow regulating valve 683 are interposed in the supply pipe 681. The supply valve 682 switches between the opening and closing of the supply pipe 681. The flow regulating valve 683 is, for example, a massflow controller, and regulates the flow rate of the rinsing liquid flowing through the supply pipe 681. The supply valve 682 and the flow regulating valve 683 are controlled by the controller 90.

In the example of FIG. 31, the wet processing unit 121W is provided with at least one guard 70 and a guard elevating driver 71. The guard 70 has a tubular shape with the rotational axis Q3 as its central axis, and surrounds the substrate holder 50. The guard 70 is capable of catching the processing liquid flying from the periphery of the substrate W. The guard elevating driver 71 moves the guard 70 upwardly and downwardly between an upper position and a lower position both to be described below. The upper position is a position in which an upper end of the guard 70 is above the substrate W held by the substrate holder 50. The guard 70, when in the upper position, is capable of catching the processing liquid flying from the periphery of the substrate W. The lower position is a position lower than the upper position and, for example, a position in which the upper end of the guard 70 is below an upper surface of the spin base 51.

In the example of FIG. 31, multiple guards 70 are provided. The multiple guards 70 are arranged concentrically. The multiple guards 70 may be used for different types of processing liquids. In the example of FIG. 31, cups 72 corresponding to the respective guards 70 are provided. Each of the cups 72 has an annular (e.g., circular) recess (groove) surrounding the rotational axis Q3. The cups 72 catch the processing liquid flowing down along the inner peripheral surfaces of the respective corresponding guards 70. Each of the cups 72 has a bottom portion, for example, connected to an upstream end of a discharge pipe 12. The processing liquid caught by each of the cups 72 is discharged through the discharge pipe 12 to the outside of the wet processing unit 121W.

### <Example of Operation of Wet Processing Unit (Electrostatic Charging Unit)>

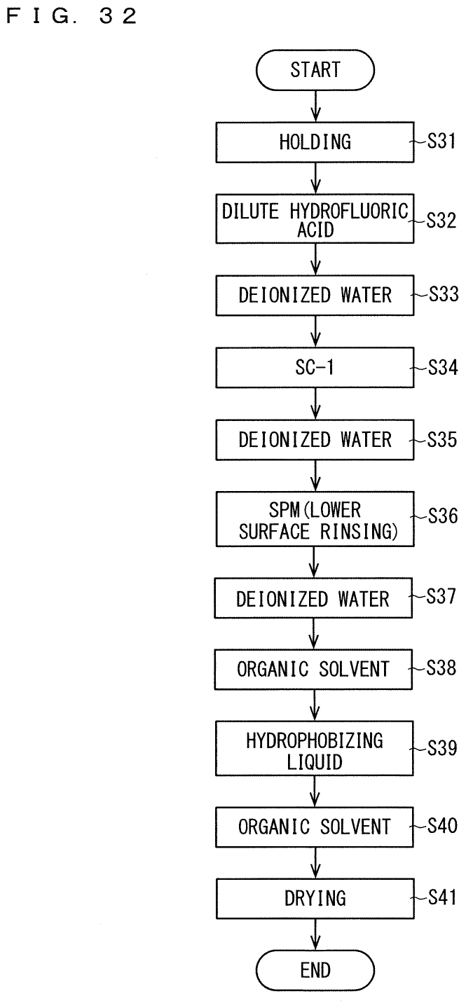

FIG. 32 is a flow diagram showing an example of the operation of the wet processing unit 121W (the electrostatic charging unit 20) according to the ninth embodiment. The controller 90 causes the wet processing unit 121W to execute Steps S31 to S41 in accordance with a preset processing procedure (recipe).

First, the second transport part 122 transports the substrate W (the substrate W with a dielectric film (SiO₂ film) formed on the second main surface Wb) to the wet processing unit 121W, and the substrate holder 50 holds the substrate W received from the second transport part 122 (Step S31: Holding step). As a specific example, the substrate holder 50 displaces the multiple chuck pins 52 from their release positions to their holding positions. Thus, the multiple chuck pins 52 hold the substrate W. The substrate holder 50 continues holding the substrate W until the completion of the processes on the substrate W.

Next, the wet processing unit 121W performs processes using various processing liquids in order on the substrate W. In the respective steps, the guard elevating driver 71 moves the guards 70 upwardly to the upper position in accordance with the processing liquids, but the description thereon is dispensed with below.

In the example of FIG. 32, the wet processing unit 121W initially performs a dilute hydrofluoric acid process (Step S32). Specifically, while the substrate holder 50 rotates the substrate W, the first dispenser 60 dispenses dilute hydrofluoric acid toward the first main surface Wa of the substrate W.

Next, the wet processing unit 121W performs a rinsing process (Step S33). Specifically, while the substrate holder 50 rotates the substrate W, the first dispenser 60 dispenses deionized water toward the first main surface Wa of the substrate W. The deionized water washes the dilute hydrofluoric acid away from the first main surface Wa of the substrate W.

Next, the wet processing unit 121W performs an SC-1 process (Step S34). Specifically, while the substrate holder 50 rotates the substrate W, the first dispenser 60 dispenses an SC-1 solution toward the first main surface Wa of the substrate W. The SC-1 solution acts on the first main surface Wa of the substrate W to clean the substrate W, for example.

Next, the wet processing unit 121W performs a rinsing process (Step S35). Specifically, while the substrate holder 50 rotates the substrate W, the first dispenser 60 dispenses deionized water toward the first main surface Wa of the substrate W. The deionized water washes the SC-1 solution away from the first main surface Wa of the substrate W.

Next, the wet processing unit 121W performs an SPM process (Step S36). Specifically, while the substrate holder 50 rotates the substrate W, the first dispenser 60 dispenses SPM toward the first main surface Wa of the substrate W.

In Step S36, the wet processing unit 121W performs a rinsing process on the second main surface Wb of the substrate W. Specifically, the second dispenser 67 dispenses a rinsing liquid toward the second main surface Wb of the substrate W which is rotating. The rinsing process performed on the second main surface Wb causes induction charging, whereby the first main surface Wa of the substrate W is positively charged. The wet processing unit 121W dispenses the rinsing liquid onto the second main surface Wb of the substrate W on processing conditions that the first main surface Wa of the substrate W is to be positively charged after the completion of a series of processes (processes until Step S41) on the substrate W. The processing conditions include, for example, the rotation speed of the substrate W, the flow rate of the rinsing liquid, and the dispensing time period of the rinsing liquid. The higher the flow rate of the rinsing liquid dispensed onto the second main surface Wb, the larger the amount of charge of the substrate W. The longer the dispensing time period of the rinsing liquid, the larger the amount of charge of the substrate W. The processing conditions of the SPM process are set in advance, for example, by simulation or experiment.

Next, the wet processing unit 121W performs a rinsing process (Step S37). Specifically, while the substrate holder 50 rotates the substrate W, the first dispenser 60 dispenses deionized water toward the first main surface Wa of the substrate W. The deionized water washes the SPM away from the first main surface Wa of the substrate W.

Next, the wet processing unit 121W performs an organic solvent process (Step S38). Specifically, while the substrate holder 50 rotates the substrate W, the first dispenser 60 dispenses an organic solvent toward the first main surface Wa of the substrate W. The organic solvent washes the deionized water away from the first main surface Wa of the substrate W.

Next, the wet processing unit 121W performs a hydrophobic process (Step S39). Specifically, while the substrate holder 50 rotates the substrate W, the first dispenser 60 dispenses a hydrophobizing liquid toward the first main surface Wa of the substrate W. The hydrophobizing liquid acts on the first main surface Wa of the substrate W to thereby hydrophobize the first main surface Wa of the substrate W. Specifically, hydrophobic groups of the hydrophobizing liquid replace the substituents of the first main surface Wa of the substrate W, whereby the first main surface Wa of the substrate W is hydrophobized. The hydrophobic groups are organic matter.

Next, the wet processing unit 121W performs an organic solvent process (Step S40). Specifically, while the substrate holder 50 rotates the substrate W, the first dispenser 60 dispenses an organic solvent toward the first main surface Wa of the substrate W. The organic solvent washes the hydrophobizing liquid away from the first main surface Wa of the substrate W. This displaces the processing liquid on the first main surface Wa of the substrate W from the hydrophobizing liquid to the organic solvent.

Next, the wet processing unit 121W performs a drying process (Step S41). Specifically, the substrate holder 50 increases the speed of rotation of the substrate W. This dries the substrate W (spin-drying). In the drying process, the first dispenser 60 may dispense gas toward the first main surface Wa of the substrate W. This allows the substrate W to dry more rapidly.

Next, the substrate holder 50 releases the holding of the substrate W, and the second transport part 122 transports the substrate W out of the wet processing unit 121W. The second transport part 122 transports the substrate W to the dry processing unit 121D.

In the ninth embodiment, as described above, the wet processing unit 121W is capable of dispensing the various processing liquids to etch or clean the substrate W.

The charged state of the first main surface Wa of the substrate W is changeable by the processing liquids supplied to the substrate W. For example, the first main surface Wa of the substrate W is negatively charged by deionized water flowing along the first main surface Wa of the substrate W. The charged state of the first main surface Wa of the substrate W after a series of processes in the case where the rinsing liquid is not supplied to the second main surface Wb of the substrate W, for example, is known in advance because the procedure for the series of processes on the substrate W is determined in advance. For this reason, the processing conditions of the rinsing process in the series of processes are set so that the rinsing process of the second main surface Wb of the substrate W positively charges the first main surface Wa of the substrate W. In other words, the wet processing unit 121W supplies the rinsing liquid (e.g., deionized water) to the second main surface Wb of the substrate W which is rotating on the processing conditions that the first main surface Wa of the substrate W is to be positively charged after the series of processes (i.e., after the drying process). As an example, the processing conditions may be conditions that the minimum value of the potential distribution of the first main surface Wa of the substrate W after the drying process is not less than a charging reference value (e.g., 10 V). This allows the wet processing unit 121W to appropriately positively charge the first main surface Wa of the substrate W while processing the substrate W.

The second dispenser 67 may supply the rinsing liquid to the second main surface Wb of the substrate W not only in Step S36 but also in other liquid processes (e.g., at least one of Steps S32 to S35).

In the aforementioned example, the hydrophobic groups, which are organic matter, are present on the first main surface Wa of the substrate W. The second transport part 122 transports the substrate W from the wet processing unit 121W to the dry processing unit 121D while maintaining the charged state of the substrate W. In the dry processing unit 121D, the transport unit 40 transports the substrate W to the gas bake unit 30 while maintaining the charged state, and the gas bake unit 30 performs the gas bake process to oxidize and remove the organic matter (the hydrophobic groups) on the substrate W. Since the first main surface Wa of the substrate W is positively charged, there is a low likelihood of the metal contamination of the substrate W even if metal ions are produced in the processing chamber 31 by the gas bake process.

In the aforementioned example, the wet processing unit 121W dries the substrate W after hydrophobizing the substrate W, but is not necessarily limited to this. The wet processing unit 121W may perform a sublimation drying process. In this case, the following steps are performed in place of Steps S38 to S41. Specifically, the wet processing unit 121W dispenses a processing liquid containing a sublimable material onto the first main surface Wa of the substrate W, and thereafter solidifies the processing liquid on the substrate W to form a solidified film of the sublimable material. Thereafter, the wet processing unit 121W sublimates the solidified film to dry the substrate W. In this case, a small amount of sublimable material (organic matter) can remain on the first main surface Wa of the substrate W.

### Tenth Embodiment

A resist may be formed on the first main surface Wa of the substrate W. The substrate processing apparatus 100 may perform a charging process for positively charging the first main surface Wa of the substrate W, a pre-bake process for heating the resist on the charged substrate W, and an exposure process for performing immersion exposure on the pre-baked substrate W. The charging process is performed by the electrostatic charging unit 20. A unit for performing the pre-bake process on the substrate W includes a hot plate for heating the substrate W. The hot plate heats the substrate W, whereby the temperature of a chamber in that unit becomes high. Thus, although metal contained in the chamber flows out in an ionic state to the interior of the chamber, the metal ions repel the positively charged substrate W. This reduces the likelihood that the substrate W is contaminated by the metal to accordingly reduce the likelihood that metal contamination is transferred to liquid in an exposure apparatus.

While the substrate processing apparatus 100 and the substrate processing method have been described hereinabove in detail, the foregoing description is in all aspects illustrative, and the present disclosure is not limited thereto. The aforementioned various modifications are applicable in combination unless the modifications are inconsistent with each other. It is therefore understood that numerous other modifications not illustrated can be devised without departing from the scope of the present disclosure.

The present disclosure includes the following aspects.

A first aspect is intended for a substrate processing apparatus which comprises: an electrostatic charging unit including an electrostatic charger for positively charging a first main surface of a substrate having the first main surface and a second main surface; and a processing unit including a processing chamber and for performing a process including at least one of the heating of the substrate in the processing chamber and the supply of a processing gas to the substrate, the process involving the generation of metal ions in the processing chamber.

A second aspect is intended for the substrate processing apparatus of the first aspect, wherein the processing unit further includes a supply pipe through which the processing gas flows, the supply pipe being connected to the processing chamber, and wherein the processing gas includes ozone gas.

A third aspect is intended for the substrate processing apparatus of the first or second aspect, wherein the electrostatic charger includes a first ionizer for charging which supplies cations to the first main surface of the substrate.

A fourth aspect is intended for the substrate processing apparatus of the third aspect, wherein the electrostatic charger further includes a flow straightener provided between an outlet of the first ionizer and the substrate.

A fifth aspect is intended for the substrate processing apparatus of the fourth aspect, wherein the electrostatic charging unit further includes a displacement driver for changing a positional relationship between the first ionizer and the substrate to change the range of supply of cations to the first main surface of the substrate.

A sixth aspect is intended for the substrate processing apparatus of the fifth aspect, wherein the displacement driver rotates at least one of the substrate and the first ionizer about a rotational axis intersecting the first main surface of the substrate.

A seventh aspect is intended for the substrate processing apparatus of the fifth or sixth aspect, wherein the displacement driver moves at least one of the substrate and the first ionizer in a direction extending along the first main surface of the substrate.

An eighth aspect is intended for the substrate processing apparatus of any one of the fifth to seventh aspects, wherein the displacement driver pivots the first ionizer.

A ninth aspect is intended for the substrate processing apparatus of any one of the first to eighth aspects, wherein the electrostatic charging unit further includes a static eliminator for eliminating static from the first main surface of the substrate.

A tenth aspect is intended for the substrate processing apparatus of the ninth aspect, wherein the static eliminator includes a second ionizer, and the second ionizer supplies cations and negative particles including at least one of electrons and anions to the first main surface of the substrate.

An eleventh aspect is intended for the substrate processing apparatus of any one of the first to tenth aspects, wherein the processing unit further includes a main body plate provided in the processing chamber and having an opposed surface facing the second main surface of the substrate in spaced apart relation, and a supporting element protruding from the opposed surface and for supporting the second main surface of the substrate, and wherein the electrostatic charger positively charges both the first main surface and the second main surface of the substrate.

A twelfth aspect is intended for the substrate processing apparatus of the eleventh aspect, wherein the electrostatic charger includes a first ionizer for supplying cations to the first main surface of the substrate and to a portion outside the first main surface of the substrate, and a guiding member for guiding cations flowing in the outside portion to the second main surface of the substrate.

A thirteenth aspect is intended for the substrate processing apparatus of the twelfth aspect, wherein the electrostatic charging unit further includes a substrate receiving part for supporting the second main surface of the substrate, multiple elevating pins, and a pin driver for moving the multiple elevating pins upwardly to lift the substrate from the substrate receiving part and for moving the multiple elevating pins downwardly to place the substrate on the substrate receiving part, wherein the electrostatic charger further includes a movement driver for moving the guiding member between a charging position and a standby position, with the multiple elevating pins supporting the substrate, wherein the charging position is a position in which part of the guiding member is interposed between the second main surface of the substrate supported by the multiple elevating pins and the substrate receiving part, and wherein the standby position is a position outside the substrate.

A fourteenth aspect is intended for the substrate processing apparatus of the eleventh aspect, wherein the electrostatic charger includes a first ionizer having an outlet for causing cations to flow out, and wherein the first ionizer is provided in a position in which the outlet faces a side surface of the substrate.

A fifteenth aspect is intended for the substrate processing apparatus of the fourteenth aspect, wherein the electrostatic charging unit further includes an elevating driver for moving one of the first ionizer and the substrate upwardly and downwardly relative to the other thereof.

A sixteenth aspect is intended for the substrate processing apparatus of any one of the first to fifteenth aspects, wherein the processing unit further includes a heater for heating the substrate as the process, and wherein the electrostatic charging unit further includes a cooler for cooling the substrate.

A seventeenth aspect is intended for the substrate processing apparatus of any one of the first to sixteenth aspects, wherein the electrostatic charging unit further includes at least one electrostatic charge sensor for measuring a potential of the first main surface of the substrate.

An eighteenth aspect is intended for the substrate processing apparatus of the seventeenth aspects, which further comprises a controller for causing the electrostatic charger to supply cations toward the first main surface of the substrate when the measured potential is less than a charging reference value.

A nineteenth aspect is intended for the substrate processing apparatus of the eighteenth aspect, wherein the electrostatic charge sensor measures the potential in multiple positions on the first main surface, and wherein the controller causes the electrostatic charger to supply cations toward at least one of the multiple positions in which the measured potential is less than the charging reference value.

A twentieth aspect is intended for the substrate processing apparatus of any one of the first to nineteenth aspects, wherein the electrostatic charger includes a substrate holder for rotating the substrate while holding the substrate, a first dispenser for dispensing multiple processing liquids in order toward the first main surface of the substrate held by the substrate holder, and a second dispenser for dispensing a rinsing liquid toward the second main surface of the substrate held by the substrate holder, wherein the electrostatic charging unit further includes a controller for controlling the substrate holder, the first dispenser, and the second dispenser to cause a series of processes to be performed on the substrate, and wherein the controller causes the second dispenser to dispense the rinsing liquid toward the second main surface of the substrate on processing conditions that the first main surface of the substrate is to be positively charged after the series of processes.

A twenty-first aspect is intended for the substrate processing apparatus of any one of the first to twentieth aspects, which further comprises a transport unit, wherein the electrostatic charging unit is provided outside the processing chamber, and wherein the transport unit includes an insulative contact portion, and transports the substrate between the electrostatic charging unit and the processing unit, with the substrate supported or held by the contact portion.

A twenty-second aspect is intended for the substrate processing apparatus of the twenty-first aspect, which further comprises: a load port on which a carrier accommodating the substrate is placed; multiple dry processing units each including the electrostatic charging unit, the transport unit, and the processing unit; and a transport robot for transporting the substrate between the load port and the multiple dry processing units.

A twenty-third aspect is intended for the substrate processing apparatus of the twenty-first aspect, which further comprises: a load port on which a carrier accommodating the substrate is placed; a relay part for relaying the substrate; a first transport robot for transporting the substrate between the carrier and the relay part; and multiple processing units each of which is the processing unit, wherein the transport unit includes a second transport unit for transporting the substrate between the relay part and the multiple processing units, and wherein the electrostatic charging unit is provided in the relay part.

A twenty-fourth aspect is intended for a method of processing a substrate, which comprises: positively charging a first main surface of a substrate having the first main surface and a second main surface; and performing a process including at least one of the heating of the substrate in a processing chamber and the supply of a processing gas to the substrate, the process involving the generation of metal ions in the processing chamber.

According to the first and twenty-fourth aspects, metal ions repel the first main surface of the substrate which is positively charged. Thus, the processing unit is capable of processing the first main surface of the substrate while reducing the likelihood that the substrate is contaminated by metal.

According to the second aspect, the ozone gas having high reactivity efficiently oxidizes and removes organic matter on the first main surface of the substrate. On the other hand, the ozone gas having high reactivity increases the danger that the metal ions flow out of the inner walls of the processing chamber and the like. However, these metal ions repel the first main surface of the substrate. As a result, there is a low likelihood that metal contamination occurs when the organic matter is oxidized and removed.

According to the third aspect, the first main surface of the substrate is positively charged. The charged state of the substrate is maintained even after the completion of the operation of the first ionizer.

According to the fourth aspect, the cations are supplied more uniformly to the first main surface of the substrate.

According to the fifth to eighth aspects, the cations are supplied more uniformly to the first main surface of the substrate, or the first ionizer which is smaller in size is employed.

According to the ninth aspect, static is eliminated from the substrate processed in the processing unit. This reduces the likelihood that particles adhere to the substrate due to static electricity.

According to the tenth aspect, static is eliminated from the substrate regardless of whether the substrate is charged positively or negatively.

According to the eleventh aspect, although the metal ions in the processing chamber can enter the gap between the opposed surface and the second main surface of the substrate, the metal ions repel the second main surface of the substrate because the second main surface of the substrate is positively charged. This reduces the likelihood that the second main surface of the substrate is contaminated by metal.

According to the twelfth aspect, the first and second main surfaces of the substrate are positively charged.

According to the thirteenth aspect, even if the substrate receiving part for supporting the second main surface of the substrate is provided, the first ionizer supplies cations while the elevating pins lift the substrate and the guiding member is moved to the charging position. Thus, the first and second main surfaces of the substrate are positively charged.

According to the fourteenth aspect, the first and second main surfaces of the substrate are positively charged with a simple configuration.

According to the fifteenth aspect, both the first and second main surfaces of the substrate are positively charged more reliably.

According to the sixteenth aspect, the substrate heated by the processing unit is cooled.

According to the seventeenth aspect, the charged state of the first main surface of the substrate is recognized.

According to the eighteenth aspect, the first main surface of the substrate is positively charged more reliably.

According to the nineteenth aspect, the first main surface of the substrate is positively charged more reliably with low power consumption.

According to the twentieth aspect, the first main surface of the substrate is positively charged while the processes in accordance with the processing liquids are performed in order on the substrate.

According to the twenty-first aspect, even if metal is contained in the electrostatic charging unit, the electrostatic charging unit does not function as a metal source to the substrate in the processing chamber when the electrostatic charging unit is provided outside the processing chamber. This further reduces the likelihood of the metal contamination of the substrate.

According to the twenty-second aspect, the electrostatic charging unit and the processing unit are provided in each of the dry processing units. This allows the processing unit to perform the process immediately after the charging process by means of the electrostatic charging unit.

According to the twenty-third aspect, there is no need to provide the electrostatic charging unit for each processing unit. This reduces manufacturing costs.

While the disclosure has been shown and described in detail, the foregoing description is in all aspects illustrative and not restrictive. It is therefore understood that numerous modifications and variations can be devised.

What is claimed is:

1. A substrate processing apparatus comprising:
an electrostatic charging unit including an electrostatic charger positively charging a first main surface of a substrate having said first main surface and a second main surface; and
a processing unit including a processing chamber and performing a process including at least one of heating of said substrate in said processing chamber and supply of a processing gas to said substrate, said process involving generation of metal ions in said processing chamber.

2. The substrate processing apparatus according to claim 1,
wherein said processing unit further includes a supply pipe through which said processing gas flows, said supply pipe being connected to said processing chamber, and
wherein said processing gas includes ozone gas.

3. The substrate processing apparatus according to claim 1,
wherein said electrostatic charger includes a first ionizer for charging which supplies cations to said first main surface of said substrate.

4. The substrate processing apparatus according to claim 3,
wherein said electrostatic charger further includes a flow straightener provided between an outlet of said first ionizer and said substrate.

5. The substrate processing apparatus according to claim 4,
wherein said electrostatic charging unit further includes
a displacement driver changing a positional relationship between said first ionizer and said substrate to change the range of supply of cations to said first main surface of said substrate.

6. The substrate processing apparatus according to claim 5,
wherein said displacement driver rotates at least one of said substrate and said first ionizer about a rotational axis intersecting said first main surface of said substrate.

7. The substrate processing apparatus according to claim 5,
wherein said displacement driver moves at least one of said substrate and said first ionizer in a direction extending along said first main surface of said substrate.

8. The substrate processing apparatus according to claim 5,
wherein said displacement driver pivots said first ionizer.

9. The substrate processing apparatus according to claim 1,
wherein said electrostatic charging unit further includes a static eliminator eliminating static from said first main surface of said substrate.

10. The substrate processing apparatus according to claim 9,
wherein said static eliminator includes a second ionizer, and said second ionizer supplies cations and negative particles including at least one of electrons and anions to said first main surface of said substrate.

11. The substrate processing apparatus according to claim 1,
wherein said processing unit further includes
a main body plate provided in said processing chamber and having an opposed surface facing said second main surface of said substrate in spaced apart relation, and
a supporting element protruding from said opposed surface and supporting said second main surface of said substrate, and
wherein said electrostatic charger positively charges both said first main surface and said second main surface of said substrate.

12. The substrate processing apparatus according to claim 11,
wherein said electrostatic charger includes
a first ionizer supplying cations to said first main surface of said substrate and to a portion outside said first main surface of said substrate, and
a guiding member guiding cations flowing in said outside portion to said second main surface of said substrate.

13. The substrate processing apparatus according to claim 12,
wherein said electrostatic charging unit further includes
a substrate receiving part supporting said second main surface of said substrate, multiple elevating pins, and
a pin driver moving said multiple elevating pins upwardly to lift said substrate from said substrate receiving part and moving said multiple elevating pins downwardly to place said substrate on said substrate receiving part,
wherein said electrostatic charger further includes a movement driver moving said guiding member between a charging position and a standby position, with said multiple elevating pins supporting said substrate,
wherein said charging position is a position in which part of said guiding member is interposed between said second main surface of said substrate supported by said multiple elevating pins and said substrate receiving part, and
wherein said standby position is a position outside said substrate.

14. The substrate processing apparatus according to claim 11,
wherein said electrostatic charger includes a first ionizer having an outlet from which cations flow out, and
wherein said first ionizer is provided in a position in which said outlet faces a side surface of said substrate.

15. The substrate processing apparatus according to claim 14,
wherein said electrostatic charging unit further includes an elevating driver moving one of said first ionizer and said substrate upwardly and downwardly relative to the other thereof.

16. The substrate processing apparatus according to claim 1,
wherein said processing unit further includes a heater heating said substrate as said process, and
wherein said electrostatic charging unit further includes a cooler cooling said substrate.

17. The substrate processing apparatus according to claim 1,
wherein said electrostatic charging unit further includes at least one electrostatic charge sensor measuring a potential of said first main surface of said substrate.

18. The substrate processing apparatus according to claim 17, further comprising
a controller causing said electrostatic charger to supply cations toward said first main surface of said substrate when said measured potential is less than a charging reference value.

19. The substrate processing apparatus according to claim 18,
wherein said electrostatic charge sensor measures said potential in multiple positions on said first main surface, and
wherein said controller causes said electrostatic charger to supply cations toward at least one of said multiple positions in which said measured potential is less than said charging reference value.

20. The substrate processing apparatus according to claim 1,
wherein said electrostatic charger includes
a substrate holder rotating said substrate while holding said substrate,
a first dispenser dispensing multiple processing liquids in order toward said first main surface of said substrate held by said substrate holder, and
a second dispenser dispensing a rinsing liquid toward said second main surface of said substrate held by said substrate holder,
wherein said electrostatic charging unit further includes a controller controlling said substrate holder, said first dispenser, and said second dispenser to cause a series of processes to be performed on said substrate, and
wherein said controller causes said second dispenser to dispense said rinsing liquid toward said second main surface of said substrate on processing conditions that said first main surface of said substrate is to be positively charged after said series of processes.

21. The substrate processing apparatus according to claim 1, further comprising
a transport unit,
wherein said electrostatic charging unit is provided outside said processing chamber, and
wherein said transport unit includes an insulative contact portion, and transports said substrate between said electrostatic charging unit and said processing unit, with said substrate supported or held by said contact portion.

22. The substrate processing apparatus according to claim 21, further comprising:
a load port on which a carrier accommodating said substrate is placed;
multiple dry processing units each including said electrostatic charging unit, said transport unit, and said processing unit; and
a transport robot transporting said substrate between said load port and said multiple dry processing units.

23. The substrate processing apparatus according to claim 21, further comprising:
a load port on which a carrier accommodating said substrate is placed;
a relay part relaying said substrate;
a first transport robot transporting said substrate between said carrier and said relay part; and
multiple processing units each of which is said processing unit,
wherein said transport unit includes a second transport unit transporting said substrate between said relay part and said multiple processing units, and
wherein said electrostatic charging unit is provided in said relay part.

24. A method of processing a substrate, comprising:
positively charging a first main surface of a substrate having said first main surface and a second main surface; and
performing a process including at least one of heating of said substrate in a processing chamber and supply of a processing gas to said substrate, said process involving generation of metal ions in said processing chamber.
